(19) United States
(12) Patent Application Publication
(10) Pub. No.: US 2014/0091430 A1
(43) Pub. Date: Apr. 3, 2014

(54) SEMICONDUCTOR DEVICE INCLUDING OPERATIVE CAPACITORS AND DUMMY CAPACITORS

(71) Applicant: Fujitsu Semiconductor Limited, Yokohama-shi (JP)

(72) Inventor: Kouichi NAGAI, Kawasaki (JP)

(73) Assignee: FUJITSU SEMICONDUCTOR LIMITED, YOKOHAMA-SHI (JP)

(21) Appl. No.: 14/046,164

(22) Filed: Oct. 4, 2013

Related U.S. Application Data
(62) Division of application No. 11/954,811, filed on Dec. 12, 2007.
Application No. 11/954,811 is a division of application No. PCT/JP2005/010801, filed on Jun. 13, 2005.

(51) Int. Cl. H01L 49/02; H01L 43/02

(52) U.S. Cl. CPC H01L 28/40; H01L 43/02
USPC 257/532

(57) ABSTRACT

The semiconductor device according to the present invention comprises a plurality of actually operative capacitors formed, arranged in an actually operative capacitor part over a semiconductor substrate and each including a lower electrode, a ferroelectric film and an upper electrode; a plurality of dummy capacitors formed, arranged in a dummy capacitor part provided outside of the actually operative capacitor part over the semiconductor substrate and each including the lower electrode, the ferroelectric film and the upper electrode; a plurality of interconnections respectively formed on said plurality of the actually operative capacitors and respectively connected to the upper electrodes of said plurality of the actually operative capacitors; and the interconnections respectively formed on said plurality of the dummy capacitors.

### CROSS REFERENCE TO RELATED APPLICATIONS

This application is a divisional of application Ser. No. 11/954,811, filed Dec. 12, 2007, which is a Continuation of International Application No. PCT/JP2005/010801, with an international filing date of Jun. 13, 2005, which designating the United States of America, the entire contents of which are incorporated herein by reference.

### DESCRIPTION OF THE RELATED ART

The embodiments discussed herein are directed to a semiconductor device including ferroelectric capacitors, more specifically, a semiconductor including ferroelectric capacitors which make actual operations, and ferroelectric capacitors which do not make the actual operations.

### BACKGROUND ART

Recently, the dielectric capacitor using a ferroelectric film as the dielectric film thereof is noted. And, the ferroelectric random access memory (FeRAM), which holds information in the ferroelectric capacitors by utilizing the polarization reversal of the ferroelectric substance, is being developed. The FeRAM has merits that the FeRAM is a nonvolatile memory, which does not lose information held therein even when the source supply is stopped, can be highly integrated, can make high-speed operations, has low electric power consumptions and has good write/read durability, and other merits.

As materials of the ferroelectric film forming the ferroelectric capacitors, ferroelectric oxides of the perovskite structure, such as PZT (PbZr_{1-X}Ti_{X}O₃), SBT(SrBi₂Ta₂O₉), etc., having large residual polarization quantities of about 10-30 μC/cm² are mainly used.

It has been conventionally known that such dielectric film has the ferroelectric characteristics deteriorated by water intruding from the outside via the inter-layer insulating film, as of, silicon oxide film or others, which is highly hydrophilic. That is, in the high-temperature processes for forming inter-layer insulating films and metal interconnections, when water is decomposed into hydrogen and oxygen, and the hydrogen intrudes into the ferroelectric film, the hydrogen reacts with the oxygen in the ferroelectric film to form oxygen defects in the ferroelectric film. These oxygen defects deteriorate the crystallinity of the ferroelectric film. The long use of the FeRAM similarly generates the phenomenon of the deterioration of the crystallinity of the ferroelectric film. When the crystallinity of the ferroelectric film is thus deteriorated, decreases of the residual polarization quantity, the dielectric constant, etc. of the ferroelectric film take place, and the performance of the ferroelectric capacitor is deteriorated. The performances of not only the ferroelectric capacitors but also the transistors, etc. are often deteriorated.

The FeRAM is a piezoelectric device, and the characteristics are changed due to stresses applied thereto. That is, in the FeRAM, to inverse “1” and “0” states stored as information corresponding to the polarization axis direction of the ferroelectric film, a slight space which is vertically movable is necessary. When the ferroelectric capacitors of the FeRAM are subjected to strong compression stresses from above or inhomogeneous stresses, inconveniences such that the FeRAM does not normally operate are caused.

In the semiconductor memory, generally dummy capacitors, which do not actually operate, are additionally arranged to thereby suppress the deterioration of the actually operative capacitors. For example, Patent Reference 1 discloses the dynamic random access memory (DRAM) including dummy capacitors uniformly arranged along the outermost boundary of the memory cell region.

In the FeRAM, the configuration, arrangement, etc. of the electrodes forming the ferroelectric capacitors are contrived to thereby suppress the scatter of the characteristics of the ferroelectric capacitors (refer to, e.g., Patent Reference 2).

In the FeRAM as well, for the end of suppressing the deterioration of the ferroelectric capacitors formed in the memory cell region, dummy capacitors are arranged along the outermost boundary, etc. of the memory cell region (refer to, e.g., Patent References 3-5).
Patent Reference 1: Japanese Published Unexamined Patent Application No. Hei 11-345946
Patent Reference 2: Pamphlet of International Publication No. WO 97/40531
Patent Reference 3: Japanese Published Unexamined Patent Application No. 2004-47943
Patent Reference 4: Japanese Published Unexamined Patent Application No. 2002-343942
Patent Reference 5: Japanese Published Unexamined Patent Application No. 2001-358312

However, in the FeRAM, it is impossible to simply arrange dummy capacitors along the outermost boundary of the memory cell region to thereby surely prevent the deterioration of the performance of the actually operative ferroelectric capacitors.

Furthermore, conventionally stresses applied to the ferroelectric capacitors from above have not been especially considered. Stresses are applied inhomogeneously to the ferroelectric capacitors from above to thereby often deteriorate the performance of the ferroelectric capacitors.

### SUMMARY

It is an aspect of the embodiments discussed herein to provide a semiconductor device including a plurality of actually operative capacitors formed, arranged in a first region over a semiconductor substrate, and each including a first lower electrode, a first ferroelectric film formed on the first lower electrode and a first upper electrode formed on the first ferroelectric film, a plurality of dummy capacitors formed, arranged in a second region provided outside of the first region over the semiconductor substrate, each including a second lower electrode, a second ferroelectric film formed on the second lower electrode and a second upper electrode formed on the second ferroelectric film, a plurality of first interconnections respectively formed over said plurality of the actually operative capacitors and respectively connected to the first upper electrodes of said plurality of the actually operative capacitors, and a plurality of second interconnections respectively formed over said plurality of the dummy capacitors, a ratio of a pitch of the dummy capacitors to a pitch of the actually operative capacitors being in a range of 0.9-1.1, and a ratio of a pitch of the second interconnections to a pitch of the first interconnections being in a range of 0.9-1.1.

### BRIEF DESCRIPTION OF DRAWINGS

FIG. 1 is a plan view showing the chip structure of the semiconductor device according to a first embodiment.

FIG. 2 is a plan view showing the arrangement of the dummy capacitor part in the memory cell region of the semiconductor device according to the first embodiment.

FIG. 3 is a plan view showing the memory cell region of the semiconductor device according to the first embodiment (Part 1).

FIG. 4 is a plan view showing the memory cell region of the semiconductor device according to the first embodiment (Part 2).

FIG. 5 is a plan view showing the structure of the ferroelectric capacitors and the interconnections of the semiconductor device according to the first embodiment.

FIG. 6 is a sectional view showing the structure of the ferroelectric capacitors and the interconnections of the semiconductor device according to the first embodiment.

FIG. 7 is a diagrammatic view explaining the mechanism for the performance deterioration of the actually operative capacitors without the interconnections formed over the dummy capacitors (Part 1).

FIG. 8 is a diagrammatic view explaining the mechanism for the performance deterioration of the actually operative capacitors without the interconnections formed over the dummy capacitors (Part 2).

FIG. 9 is a graph of the result of evaluating the lifetime characteristics of the FeRAM of the first embodiment.

FIG. 10 is a graph of the result of evaluating the lifetime characteristics of the conventional FeRAM.

FIG. 11A is a sectional view showing the method of manufacturing the semiconductor device according to the first embodiment (Part 1).

FIG. 11B is another sectional view showing the method of manufacturing the semiconductor device according to the first embodiment (Part 1).

FIG. 12A is a sectional view showing the method of manufacturing the semiconductor device according to the first embodiment (Part 2).

FIG. 12B is another sectional view showing the method of manufacturing the semiconductor device according to the first embodiment (Part 2).

FIG. 13A is a sectional view showing the method of manufacturing the semiconductor device according to the first embodiment (Part 3).

FIG. 13B is another sectional view showing the method of manufacturing the semiconductor device according to the first embodiment (Part 3).

FIG. 14A is a sectional view showing the method of manufacturing the semiconductor device according to the first embodiment (Part 4).

FIG. 14B is another sectional view showing the method of manufacturing the semiconductor device according to the first embodiment (Part 4).

FIG. 15A is a sectional view showing the method of manufacturing the semiconductor device according to the first embodiment (Part 5).

FIG. 15B is another sectional view showing the method of manufacturing the semiconductor device according to the first embodiment (Part 5).

FIG. 16A is a sectional view showing the method of manufacturing the semiconductor device according to the first embodiment (Part 6).

FIG. 16B is another sectional view showing the method of manufacturing the semiconductor device according to the first embodiment (Part 6).

FIG. 17A is a sectional view showing the method of manufacturing the semiconductor device according to the first embodiment (Part 7).

FIG. 17B is another sectional view showing the method of manufacturing the semiconductor device according to the first embodiment (Part 7).

FIG. 18 is a sectional view showing the method of manufacturing the semiconductor device according to the first embodiment (Part 8).

FIG. 19 is a sectional view showing the method of manufacturing the semiconductor device according to the first embodiment (Part 9).

FIG. 20 is a sectional view showing the method of manufacturing the semiconductor device according to the first embodiment (Part 10).

FIG. 21 is a sectional view showing the structure of the semiconductor device according to a second embodiment.

FIG. 22A is a sectional view showing the method of manufacturing the semiconductor device according to the second embodiment (Part 1).

FIG. 22B is another sectional view showing the method of manufacturing the semiconductor device according to the second embodiment (Part 1).

FIG. 23A is a sectional view showing the method of manufacturing the semiconductor device according to the second embodiment (Part 2).

FIG. 23B is another sectional view showing the method of manufacturing the semiconductor device according to the second embodiment (Part 2).

FIG. 24 is a sectional view showing the structure of the semiconductor device according to a third embodiment.

FIG. 25A is a sectional view showing the method of manufacturing the semiconductor device according to the third embodiment of the present invention.

FIG. 25B is another sectional view showing the method of manufacturing the semiconductor device according to the third embodiment of the present invention.

FIG. 26 is a sectional view showing the structure of the semiconductor device according to a modification of the third embodiment.

FIG. 27 is a plan view showing the structure of the semiconductor device according to a fourth embodiment.

FIG. 28 is a plan view showing the structure of the semiconductor device according to a fifth embodiment.

FIG. 29 is a sectional view showing the structure of the semiconductor device according to the fifth embodiment.

FIG. 30A is a plan view explaining the displacements of the arrangement of the dummy capacitors from the arrangement of the actually operative capacitors.

FIG. 30B is another plan view explaining the displacements of the arrangement of the dummy capacitors from the arrangement of the actually operative capacitors.

### DETAILED DESCRIPTION OF THE EMBODIMENTS

### A First Embodiment

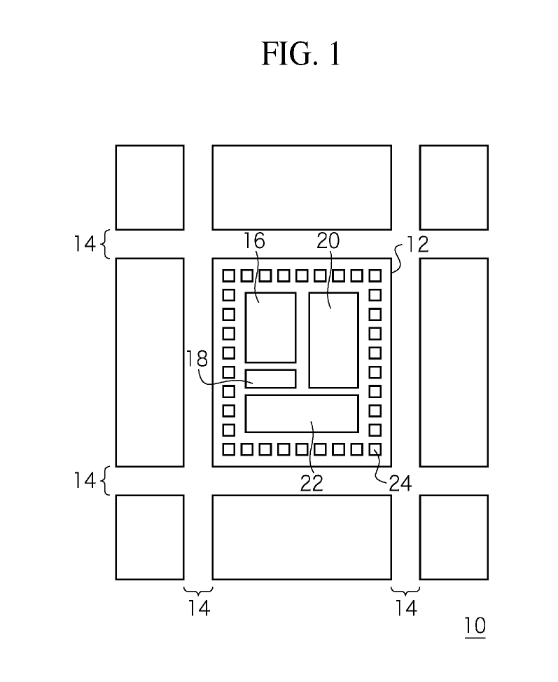

The semiconductor device and the method of manufacturing the same according to a first embodiment will be explained with reference to FIGS. 1 to 20.

First, the structure of the semiconductor device according to the present embodiment will be explained with reference to FIGS. 1 to 10.

First, the chip structure of the semiconductor device according to the present embodiment will be explained with reference to FIG. 1. FIG. 1 is a plan view showing the chip structure of the semiconductor device according to the present embodiment.

As illustrated, a plurality of FeRAM chip regions 12 are formed in a semiconductor substrate 10. Scribe regions 14 which are cut regions for separating the respective FeRAM chip regions 12 into discrete FeRAM chips are provided between the adjacent FeRAM chip regions 12.

In each FeRAM chip region 12, a memory cell region 16, its peripheral circuit region 18, a logic circuit region 20 and its peripheral circuit region 22 are provided. In the peripheral part of the FeRAM chip region 12, bonding pads 24 for connecting the chip circuits to outside circuits are provided. The bonding pads 24 may be formed along all the sides of the peripheral part of the rectangular FeRAM chip region 12 or along only a pair of opposed sides, corresponding to a kind, etc. of the package of the FeRAM.

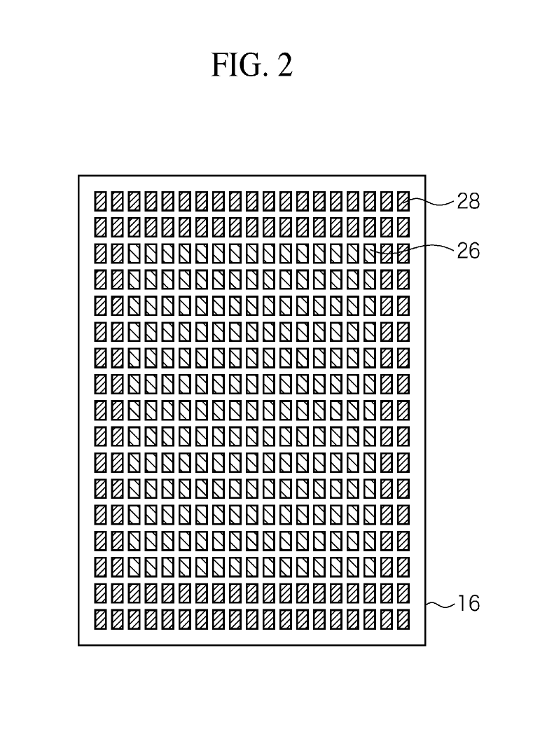

In the semiconductor device according to the present embodiment, in the memory cell region 16, a dummy capacitor part where dummy capacitors are formed is provided. The arrangement of the dummy capacitor part in the memory cell region 16 will be explained with reference to FIG. 2. FIG. 2 is a plan view showing the arrangement of the dummy capacitor part in the memory cell region of the semiconductor device according to the present embodiment.

As illustrated, in the memory cell region 16, actually operative capacitor parts 26, where ferroelectric capacitors (actually operative capacitors) which actually operate to store information as the FeRAM are formed, are arranged in an array. On the outside of the boundary of the arrangement of the actually operative capacitor parts 26, dummy capacitor parts 28, where ferroelectric capacitors (dummy capacitors) which do not actually operate to store information as the FeRAM, are arranged.

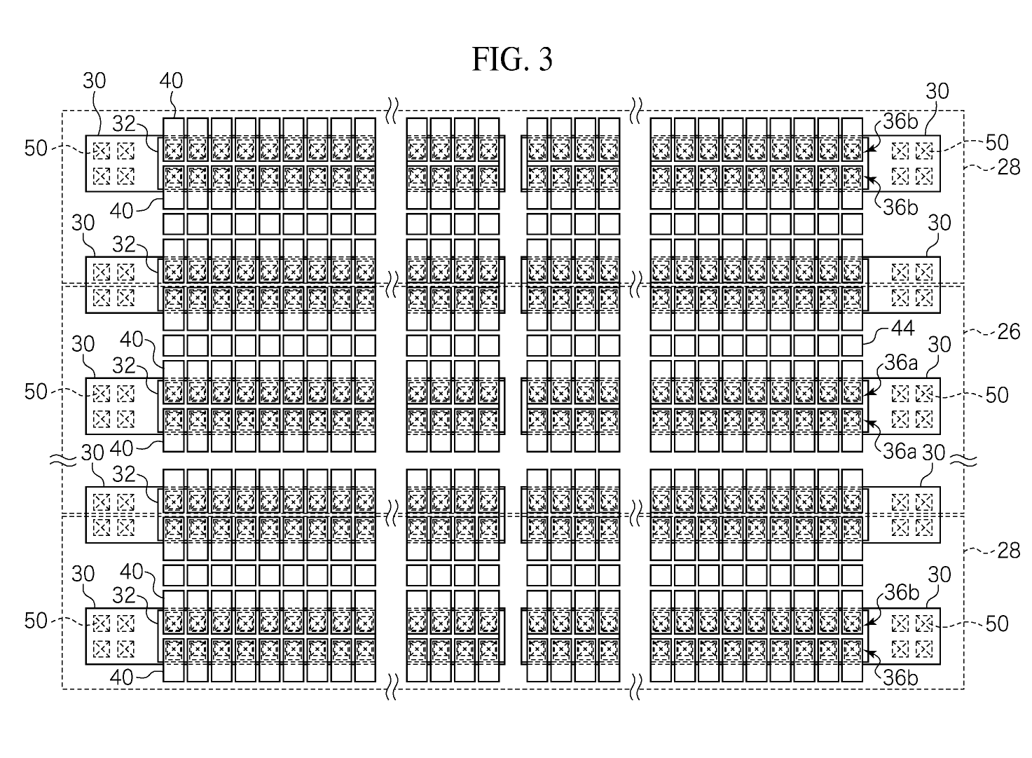

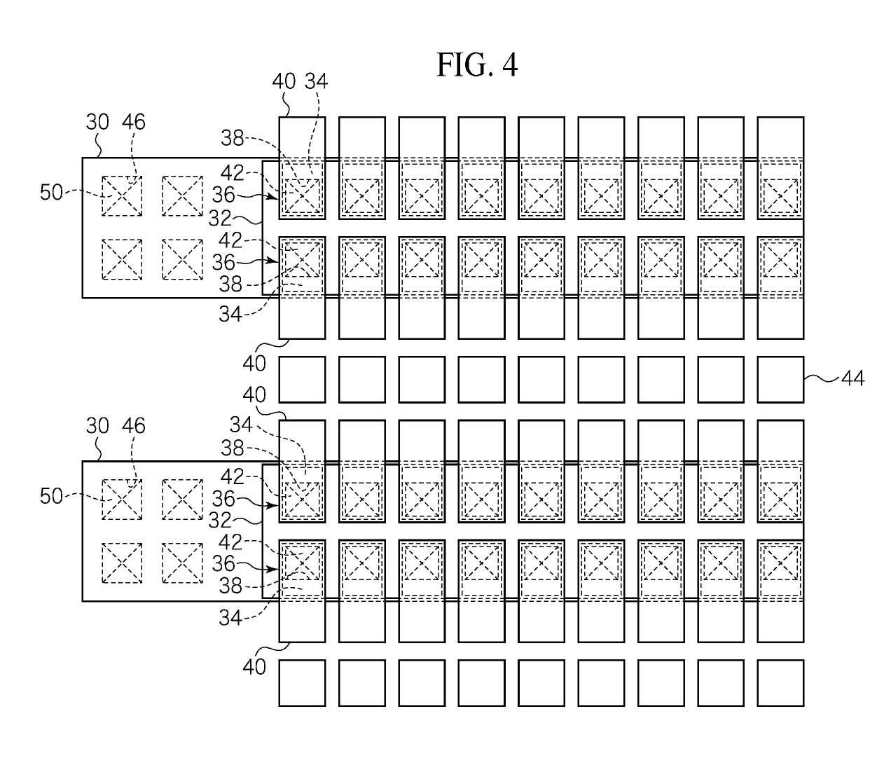

Then, the plane structure of the memory cell region 16, where the actually operative capacitor parts and the dummy capacitor parts 28 are thus formed, will be explained with reference to FIGS. 3 and 4. FIG. 3 is a plan view showing the memory cell region of the semiconductor device according to the present embodiment, and FIG. 4 is an enlarged plan view of a part of the plan view of FIG. 3.

As illustrated in FIGS. 3 and 4, in the memory cell region 16, strips of lower electrodes 30 are formed over the semiconductor substrate 10 with an inter-layer insulating film formed therebetween. On the strips of lower electrodes 30, strips of ferroelectric film 32 are formed along the longer direction thereof. On the strips of ferroelectric film 32, a plurality of rectangular upper electrodes 34 are formed spaced from each other. The upper electrodes 34 are formed two along the width of the ferroelectric film 32. Thus, on one lower electrode 30, planar ferroelectric capacitors 36 each including the lower electrode 30, the ferroelectric film 32 and the upper electrode 34 are formed by a number of the upper electrodes 34.

In the memory cell region 16 with the ferroelectric capacitors 36 thus formed in, as illustrated in FIG. 3, the ferroelectric capacitors 36 positioned in the actually operative capacitor part 26 enclosed by the dummy capacitor part 28 form memory cells of the FeRAM and are actually operative capacitors 36a, which actually operate to store information. The ferroelectric capacitors 36 in the dummy capacitor part 28 are dummy capacitors 36b, which do not actually operate and do not store information. The actually operative capacitors 36a and the dummy capacitors 36b have the same plane shape and the same area, and are arranged at the same pitch.

Above the ferroelectric capacitors 36, interconnections 40 are formed, connected to the upper electrodes 34 via contact holes 38 formed in an inter-layer insulating film. In the contact holes 38, plug portions 42 of the interconnections 40 are buried. The interconnections 40 and their plug portions 42 formed above the actually operative capacitors 36a and the interconnections 40 and their plug portions 42 formed above the dummy capacitors 36b have the same plane shape and the same area, and are arranged at the same pitch.

On the same level as the interconnections 40, interconnections 44 to which bit lines are connected are formed. The bit lines are formed upper of the interconnections 44.

In the inter-layer insulating film on the lower electrodes 30, contact holes 46 are formed down to the lower electrodes 30. In the contact holes 46, plug portions 50 are buried for connecting the lower electrodes 30 and the interconnections.

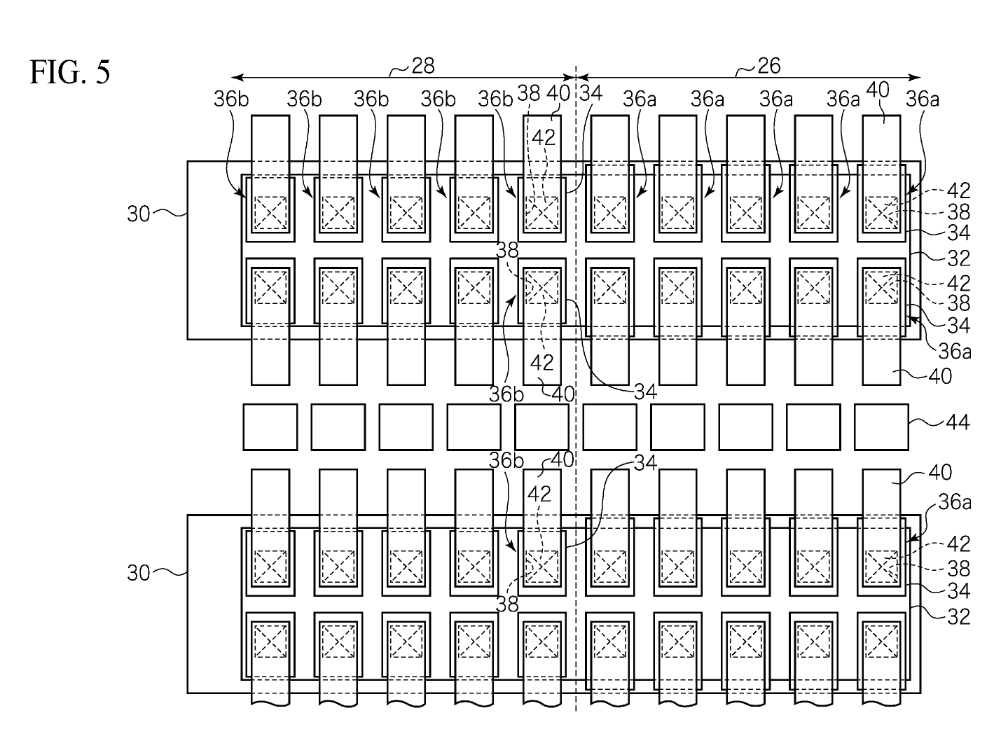

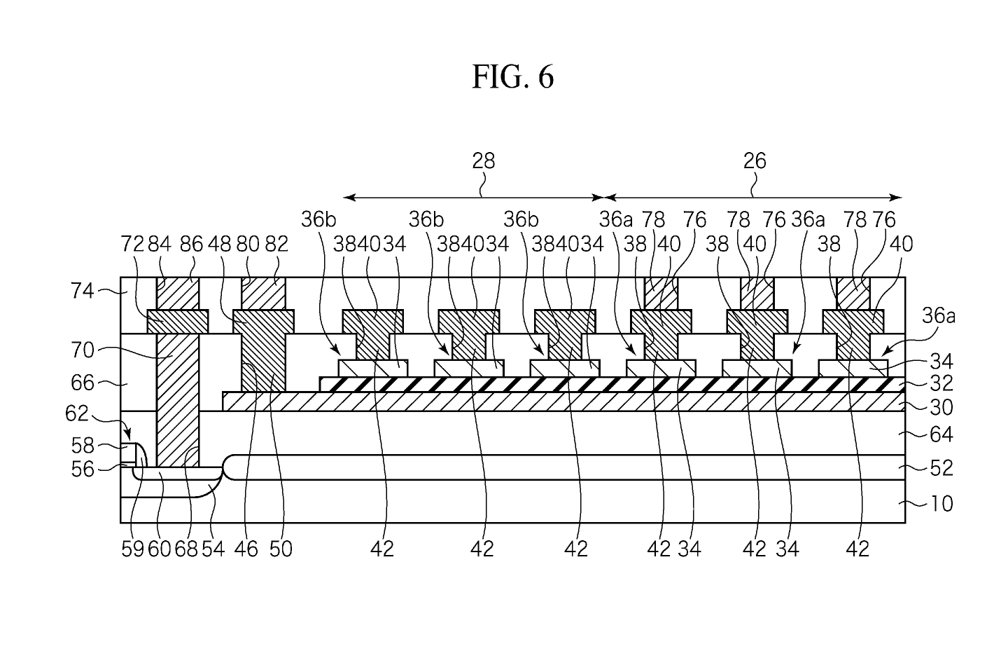

Then, the structure of the actually operative capacitors and the dummy capacitors of the semiconductor device according to the present embodiment, and the structure of the interconnections arranged for them will be detailed with reference to FIGS. 5 and 6. FIG. 5 is a plan view showing the structure of the actually operative capacitors, etc. of the semiconductor device according to the present embodiment, and FIG. 6 is a sectional view showing the structure of the actually operative capacitors, etc. of the semiconductor device according to the present embodiment. In FIGS. 5 and 6, the actually operative capacitor and the dummy capacitor include the common lower electrode and the common ferroelectric film.

On the semiconductor substrate 10 in the memory cell region 16, the actually operative capacitor part 26 where the actually operative capacitors 36a are formed, and the dummy capacitor part 28 where the dummy capacitors 36b are formed are provided.

In the semiconductor substrate 10 of, e.g., silicon, a device isolation region 52 is formed. In the semiconductor substrate 10 with the device isolation region 52 formed in, wells 54 are formed.

On the semiconductor substrate 10 with the wells 54 formed in, gate electrodes 58 are formed with a gate insulation film 56 formed therebetween. On the side wall of each gate electrode 58, a sidewall insulation film 59 is formed. On both sides of each gate electrode 58, source/drain regions 60 are formed. Thus, on the semiconductor substrate 10, transistors 62 each including the gate electrode 58 and the source/drain regions 60 are formed.

On the semiconductor substrate 10 with the transistors 62 formed on, an inter-layer insulating film 64 is formed.

On the inter-layer insulating film 64, the lower electrode 30 which is common between the actually operative capacitors 36a and the dummy capacitors 36b is formed. The lower electrode 30 is formed in a strip.

On the lower electrode 30 in the actually operative capacitor part 26 and the dummy capacitor part 28, the ferroelectric film 32 which is common between the actually operative capacitors 36a and the dummy capacitors 36b is formed. The ferroelectric film 32 is formed in a strip along the longer direction of the strip of lower electrode 30.

On the strip of the ferroelectric film 32, a plurality of the rectangular upper electrodes 34 are formed along the longer direction thereof, spaced from each other. Along the width of the ferroelectric film 32, the upper electrodes 34 formed two. Thus, in the actually operative capacitor part 26, the actually operative capacitors 36a each including the lower electrode 30, the ferroelectric film 32 and the upper electrode 34 are formed. In the dummy capacitor part 28, the dummy capacitors 36b each including the lower electrode 30, the ferroelectric film 32 and the upper electrode 34 are formed. The actually operative capacitors 36a and the dummy capacitors 36b are formed on the same level from the semiconductor substrate 10.

As illustrated in FIG. 5, the upper electrodes 34 of the actually operative capacitors 36a and the upper electrodes 34 of the dummy capacitors 36b have the substantially same plane shape and the substantially same area, and are arranged at the substantially same pitch. That is, the actually operative capacitors 36a and the dummy capacitors 36b have the substantially same plane shape and the substantially same area, and are arranged at the substantially same pitch.

On the inter-layer insulating film 64 with the actually operative capacitors 36a and the dummy capacitors 36b formed on, an inter-layer insulating film 66 is formed.

In the inter-layer insulating film 66 in the actually operative capacitor part 26, the contact holes 38 are formed down to the upper electrodes 34 of the actually operative capacitors 36a. In the inter-layer insulating film 66 in the dummy capacitor part 28, the contact holes 38 are formed down to the upper electrodes 34 of the dummy capacitors 36b.

In the inter-layer insulating film 66, the contact holes 46 are formed down to the lower electrodes 30.

In the inter-layer insulating films 64, 66, contact holes 68 are formed down to the source/drain regions 60.

On the inter-layer insulating film 66 in the actually operative capacitor part 26, the interconnections 40 are formed, connected to the upper electrodes 34 of the actually operative capacitors 36a via the contact holes 38. The interconnection 40 has the plug portion 42 buried in the contact hole 38 and connected to the upper electrode 34 of the actually operative capacitor 36a integrated.

Similarly, on the inter-layer insulating film 66 in the dummy capacitor part 28, the interconnections 40 are formed, connected to the upper electrodes 34 of the dummy capacitors 36b via the contact holes 38. The interconnection 40 has the plug portion 42 buried in the contact hole 38 and connected to the upper electrode 34 of the dummy capacitor 36b integrated.

The interconnections 40 connected to the upper electrodes 34 of the actually operative capacitors 36a and the interconnections 40 connected to the upper electrodes 34 of the dummy capacitors 36b are formed on the same level from the semiconductor substrate 10. The plug portions 42 of the interconnections 40 connected to the upper electrodes 34 of the actually operative capacitors 36a and the plug portions 42 of the interconnections 40 connected to the upper electrodes 34 of the dummy capacitors 36b are formed on the same level from the semiconductor substrate 10.

As illustrated in FIG. 5, the interconnections 40 connected to the upper electrodes 34 of the actually operative capacitors 36a and the interconnections 40 connected to the upper electrodes 34 of the dummy capacitors 36b have the same plane shape and the same area, and are arranged at the same pitch. More specifically, the interconnections 40 have a rectangular plane shape and have the longer direction orthogonally intersecting the arrangement direction (the transverse direction as viewed in the drawing) of the actually operative capacitors 36a and the dummy capacitors 36b. The plug portions 42 of the interconnections 40 connected to the upper electrodes 34 of the actually operative capacitors 36a and the plug portions 42 of the interconnections 40 connected to the upper electrodes 34 of the dummy capacitors 36b have the same plane shape and the same area, and are arranged at the same pitch. The plug portions 42 have a rectangular plane shape.

On the inter-layer insulating film 66, interconnections 48 are formed, connected to the lower electrodes 30 via the contact holes 46. The interconnection 48 has the plug portion 50 buried in the contact hole 36 and connected to the lower electrode 30 integrated.

In the contact holes 68 formed in the inter-layer insulating films 64, 66, contact plugs 70 are buried, connected to the source/drain regions 60. On the contact plugs 70 and the inter-layer insulating film 66, interconnections 72 are formed, connected to the contact plugs 70.

On the inter-layer insulating film 66 with the interconnections 40, 48, 72 formed on, an inter-layer insulating film 74 is formed.

In the inter-layer insulating film 74 in the actually operative capacitor part 26, contact holes 76 are formed down to the interconnections 40. In the contact holes 76, contact plugs 78 are buried, connected to the interconnections 40.

In the dummy capacitor part 28, the contact plugs 78 connected to the interconnections 40 are not formed. Accordingly, the interconnections 40 electrically connected to the upper electrodes 34 of the dummy capacitors 36b are electrically isolated from the other interconnections to be dummy interconnections.

In the inter-layer insulating film 74, contact holes 80 are formed down to the interconnections 48. In the contact holes 80, contact plugs 82 are buried, connected to the interconnections 48.

In the inter-layer insulating film 74, contact holes 84 are formed down to the interconnections 72. In the contact holes 84, contact plugs 86 are buried, connected to the interconnections 72.

On the inter-layer insulating film 74, interconnection layers are suitably formed as required by a design of the FeRAM.

Thus, the semiconductor device according to the present embodiment is constituted.

The semiconductor device according to the present embodiment is firstly characterized mainly in that the interconnections 40 are also formed over the dummy capacitors 36b in the same manner as the interconnections 40 formed over the actually operative capacitors 36a.

It is known that the performance of the ferroelectric capacitor is deteriorated due to hydrogen and water. To prevent this, generally in the FeRAM, dummy capacitors are arranged along the outermost boundary of the arrangement of actually operative capacitors to thereby suppress the deterioration of the performance of the actually operative capacitors due to hydrogen and water residing in the inter-layer insulating films of silicon oxide, etc.

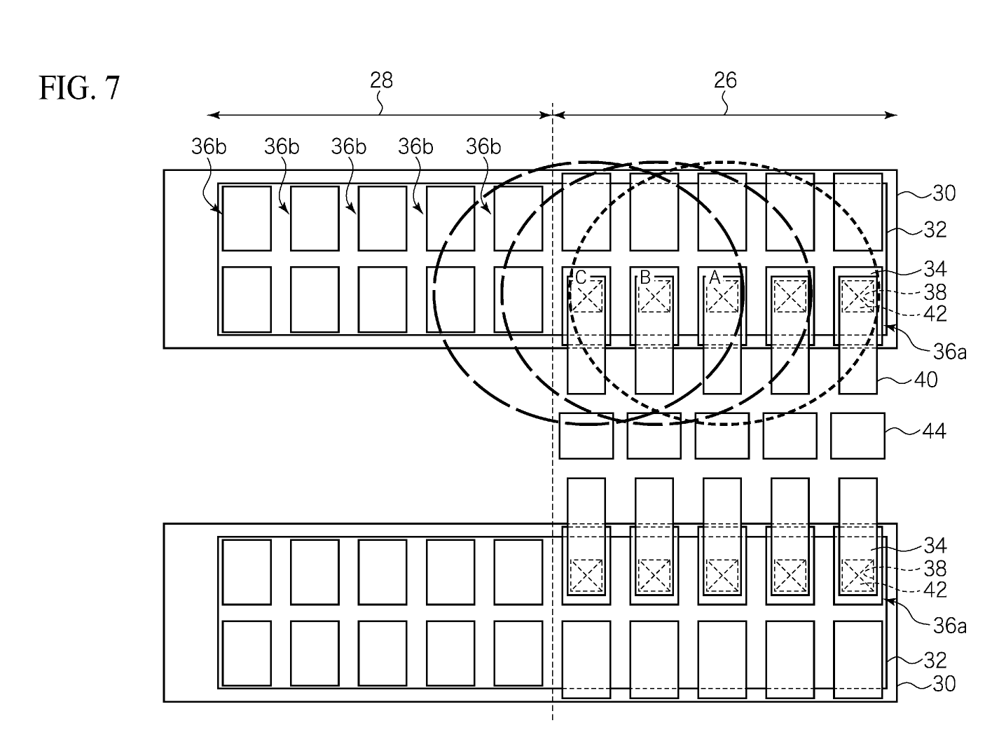

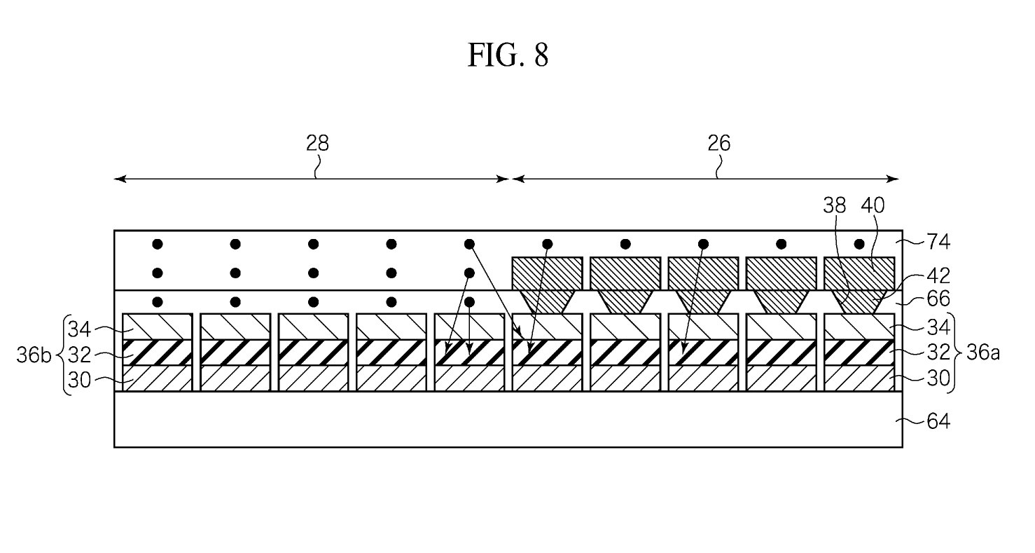

However, with the dummy capacitors simply arranged, the phenomenon that the deterioration of the performance starts gradually from the actually operative capacitors positioned at the outermost boundary of the arrangement has taken place. A cause for such phenomenon will be that no interconnections are formed over the dummy capacitors. The mechanism for the performance deterioration of the actually operative capacitors in the case that no interconnections are formed on the dummy capacitors will be explained with reference to FIGS. 7 and 8. FIGS. 7 and 8 are diagrammatic views explaining the mechanism for the performance deterioration of the actually operative capacitors without the interconnections formed over the dummy capacitors.

FIG. 7 is a plan view of the actually operative capacitor part and the dummy capacitor part without interconnections formed over the dummy capacitors. As illustrated, in the actually operative capacitor part 26, as shown in FIG. 5, the interconnections 40 are formed over the actually operative capacitors 36a, connected to the upper electrodes 34 thereof. Over the dummy capacitors 36b, however, no interconnections 40 connected to the upper electrodes thereof are formed.

In this case, in the region enclosed by the circle with the actually operative capacitor 36a indicated by “A” in the drawing centered, the interconnections 40 and plug portions 42 are formed symmetrical transversely as viewed in the drawing. However, in the regions enclosed by the circles with the actually operative capacitors 36a indicated by “B” and “C” in the drawing centered, the interconnections 40 and plug portions 42 are not formed symmetrical transversely as viewed in the drawing.

Thus, without interconnections formed over the dummy capacitors, at the end of the actually operative capacitor part 26, the interconnection structure over the actually operative capacitors 36a is inhomogeneous. Resultantly, the actually operative capacitors 36a at the end of the actually operative capacitor part 26 are subjected to inhomogeneous stresses and have the performance deteriorated.

The actually operative capacitors 36a at the end of the actually operative capacitor part 26 are susceptible to the influence of hydrogen and water in the inter-layer insulating films because of no interconnections formed over the dummy capacitors 36b, as will be described below.

FIG. 8 is a sectional view showing the actually operative capacitor part and the dummy capacitor part with no interconnections formed over the dummy capacitors. In FIG. 8, the lower electrode 30 and the ferroelectric film 32 are patterned for each of the actually operative capacitors 36 and the dummy capacitors 36b, as are not in FIG. 6.

As illustrated, the inter-layer insulating films 66, 74 are formed in the region over the dummy capacitors 36b, where the plug portions 42 and the interconnections 40 are not formed. Thus, over the dummy capacitors 36b, the inter-layer insulating films 66, 74 are present in a larger volume than above the actually operative capacitors 36a. Accordingly, over the dummy capacitors 36b, more hydrogen and water reside in the inter-layer insulating films 66, 74 than over the actually operative capacitors 36a. In the drawing, the hydrogen and water residing in the inter-layer insulating films 66, 74 are indicated schematically by the marks.

Resultantly, the actually operative capacitors 36a positioned at the end of the actually operative capacitor part 26 are susceptible to the influence of hydrogen and water from the side of the dummy capacitor part 28.

As described above, with no interconnections 40 formed over the dummy capacitors 36b, the deterioration of the performance starts from the actually operative capacitors 36a at the end of the actually operative capacitor part 26 due to inhomogeneous stresses, and the influence of hydrogen and water from side of the dummy capacitor part 28.

In the semiconductor device according to the present embodiment, on the other hand, the interconnections 40 including the plug portions 42 are formed over the dummy capacitors 36b, as are formed over the actually operative capacitors 36a. Accordingly, the volume of the inter-layer insulating films 66, 74 over the dummy capacitors 36b is decreased, as is over the actually operative capacitors 36a. Resultantly, the hydrogen and water residual amounts over the dummy capacitors 36b are decreased. Thus, the influence of the hydrogen and water from the side of the dummy capacitor part 28 on the actually operative capacitors 36a at the end of the actually operative capacitor part 26 can be suppressed. Accordingly, the performance deterioration of the actually operative capacitors 36a at the end of the actually operative capacitor part 26 can be suppressed.

Furthermore, in the semiconductor device according to the present embodiment, the interconnections 40 connected to the upper electrodes 34 of the actually operative capacitors 36a, and the interconnections 40 connected to the upper electrodes 34 of the dummy capacitors 36b have the same plane shape and the same area, and are arranged at the same pitch. The plug portions 42 of the interconnections 40 connected to the upper electrodes 34 of the actually operative capacitors 36a and the plug portions 42 of the interconnections 40 connected to the upper electrodes 34 of the dummy capacitors 36b have the same plane shape and the same area, and are arranged at the same pitch. Accordingly, the hydrogen and water residual amounts over the actually operative capacitors 36a and the hydrogen and water residual amounts over the dummy capacitors 36b can be evenly decreased. Furthermore, the interconnection structure over the dummy capacitors 36b is thus made the same as that over the actually operative capacitors 36a, whereby the stresses applied to the actually operative capacitors 36a at the end of the actually operative capacitor part 26 can be made homogeneous. Thus, the deterioration of the performance starting from the actually operative capacitors 36a at the end of the actually operative capacitor part 26 can be more surely suppressed.

Thus, according to the present embodiment, the deterioration of the performance starting from the actually operative capacitors 36a at the end of the actually operative capacitor part 26 can be surely suppressed, whereby the lifetime characteristics of the FeRAM can be improved.

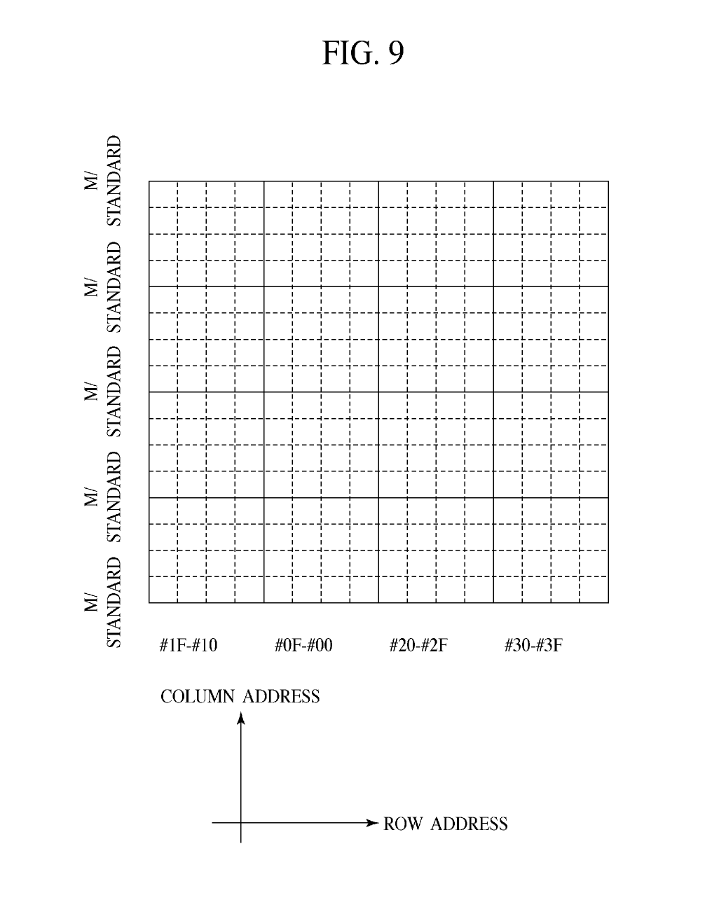

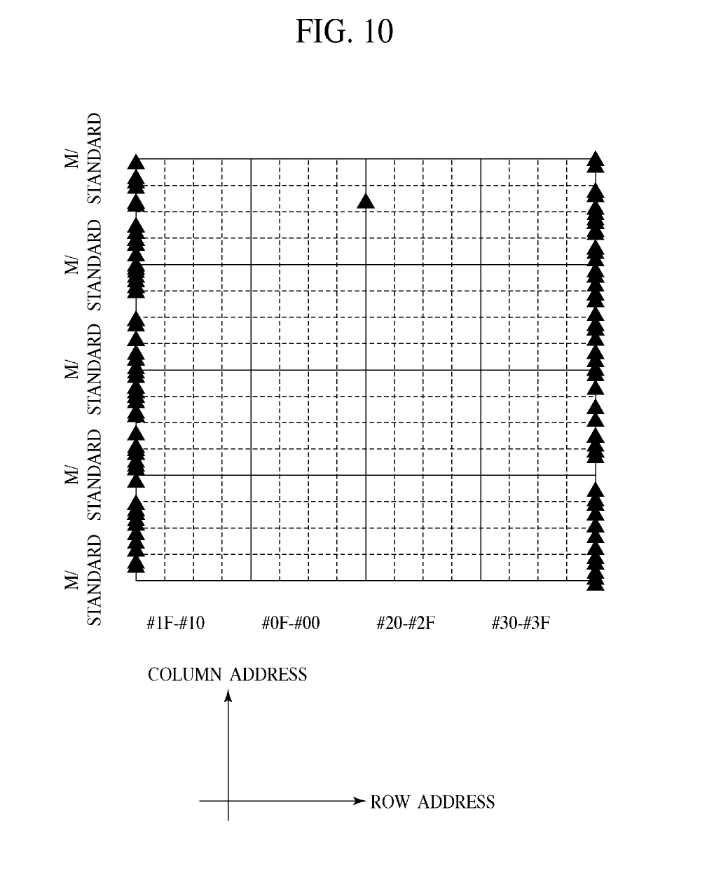

FIG. 9 is a graph of the result of evaluating the lifetime characteristics of the FeRAM according to the present embodiment. FIG. 10 is a graph of the result of evaluating the lifetime characteristics of the conventional FeRAM with no interconnections formed over the dummy capacitors. The addresses of the memory cell region are taken on the horizontal axis and the vertical axis of each graph. The addresses where defects took place are indicated by the ▴ marks.

In the conventional FeRAM, as evident in the graph of FIG. 10, defects took place in the addresses at the outermost boundary of the memory cell region.

In the FeRAM according to the present embodiment, however, no defect took place at the point when defects took place in the conventional FeRAM. Based on this, it has been confirmed that the present embodiment can drastically improve the lifetime characteristics of the FeRAM.

Patent Reference 3 discloses a semiconductor device including a plurality of actually operative capacitors formed in an array in the memory cell region, and dummy capacitors formed at the four corners of the memory cell region or at the outer boundary of the memory cell region. In Patent Reference 3, interconnections are formed over the dummy capacitors but are not formed in the same manner as the interconnections over the actually operative capacitors. Accordingly, the technique disclosed in Patent Reference 3 cannot evenly decrease the hydrogen and water amounts over the actually operative capacitors and over the dummy capacitors. Furthermore, the end of the array of the actually operative capacitors is subjected to inhomogeneous stresses. Thus, the technique disclosed in Patent Reference 3 cannot suppress the deterioration of the performance of the actually operative capacitors at the end of the actually operative capacitor part.

Patent Reference 4 discloses a semiconductor memory device including dummy capacitors formed in the connection region and the peripheral circuit region outside the memory cell region. In Patent Reference 4, interconnections are formed over the dummy capacitors in the connection region and the peripheral circuit region. However, Patent Reference 4 neither discloses nor suggests the relationship between the interconnection structure over the dummy capacitors and the interconnection structure over the ferroelectric capacitors in the memory cell region. The technique disclosed in Patent Reference 4 is intrinsically for connecting the lower electrodes of the dummy capacitors to the silicon substrate for the heat transfer between both, and is substantially different from the technique.

Patent Reference 5 discloses a semiconductor memory device including dummy ferroelectric memory cells without bit line contacts provided around the actual memory cell array. Patent Reference 5 describes the dummy interconnection, as of dummy bit lines, etc. However, based on that the dummy ferroelectric memory cells have no bit line contacts, it is considered that no plugs for connecting the upper electrodes of the dummy capacitors and the interconnections are formed. Accordingly, the technique disclosed in Patent Reference 5 cannot sufficiently decrease the hydrogen and water residual amounts on the dummy capacitors. Patent Reference 5 does not detail the arrangement of the dummy interconnections. Thus, the technique disclosed in Patent Reference 5 cannot either make stresses applied to the capacitors at the end of the actual memory cell array homogeneous.

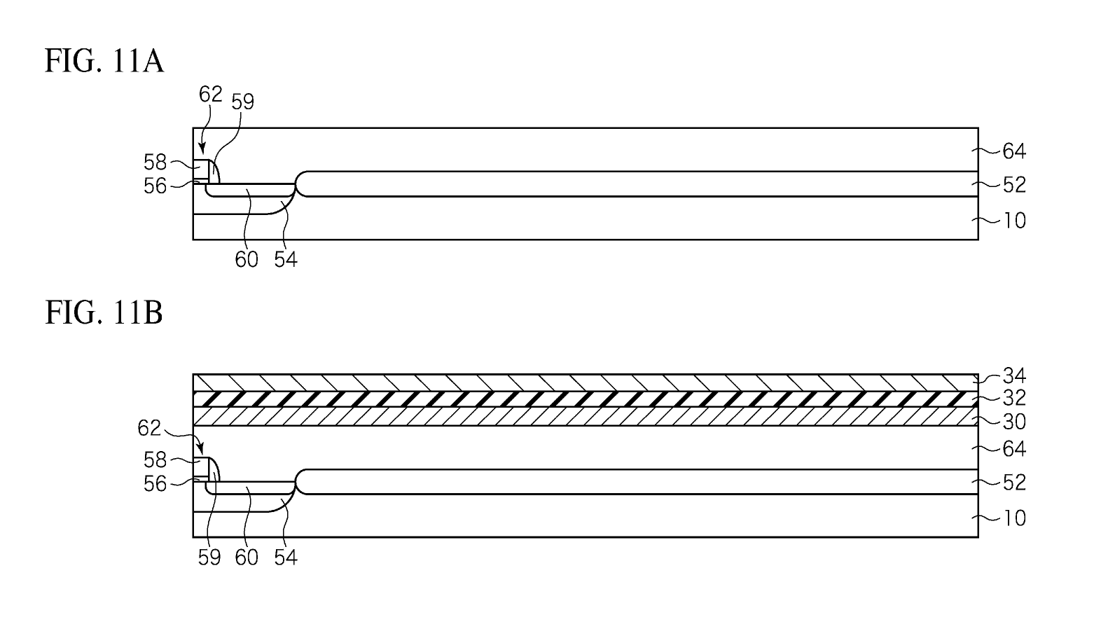

Next, the method of manufacturing the semiconductor device according to the present embodiment will be explained with reference to FIGS. 11 to 20. FIGS. 11 to 20 are sectional views showing the method of manufacturing the semiconductor device according to the present embodiment.

First, on the semiconductor substrate 10 with transistors formed on, a silicon oxide film is deposited by, e.g., CVD to form the inter-layer insulating film 64 of the silicon oxide film. Then, the surface of the inter-layer insulating film 64 is planarized by, e.g., CMP (see FIG. 11A).

Next, on the inter-layer insulating film 64, the conducting film 30 to be the lower electrodes of the ferroelectric capacitors is formed by, e.g., sputtering. As the conducting film 30, the layer film, e.g., of a titanium film and a platinum film sequentially laid is formed.

Next, on the conducting film 30, the ferroelectric film 32 of, e.g., a PZT film is formed by, e.g., sputtering.

Then, on the ferroelectric film 32, the conducting film 34 to be the upper electrodes of the ferroelectric capacitors is formed (see FIG. 11B). As the conducting film, the layer film, e.g., of an iridium oxide film and a platinum film sequentially laid is formed.

Next, on the entire surface, a photoresist film 88 is formed by, e.g., spin coating.

Next, by photolithography, the photoresist film 88 is patterned into the plane shape of the upper electrodes.

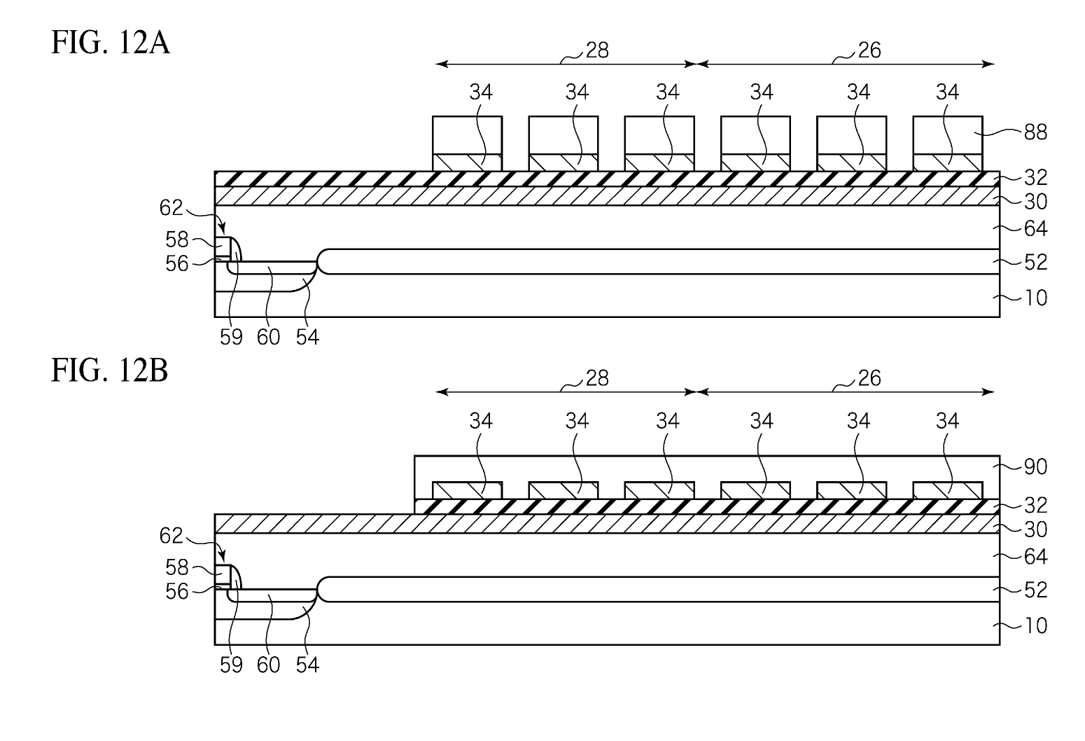

Then, with the photoresist film 88 as the mask, the conducting film 34 is etched. Thus, in the actually operative capacitor part 26 and the dummy capacitor part 28, the upper electrodes 34 of the conducting film are formed (see FIG. 12A). Then, the photoresist film 88 is removed.

Next, on the entire surface, a photoresist film 90 is formed by, e.g., spin coating.

Next, by photolithography, the photoresist film 90 is patterned into the plane shape of the ferroelectric film 32 which is common between the actually operative capacitors 36a and the dummy capacitors 36b.

Next, with the photoresist film 90 as the mask, the ferroelectric film 32 is etched (see FIG. 12B). Then, the photoresist film 90 is removed.

Next, on the entire surface, a photoresist film 92 is formed by, e.g., spin coating.

Then, by photolithography, the photoresist film 92 is patterned into the plane shape of the lower electrode 30 which is common between the actually operative capacitors 36a and the dummy capacitors 36b.

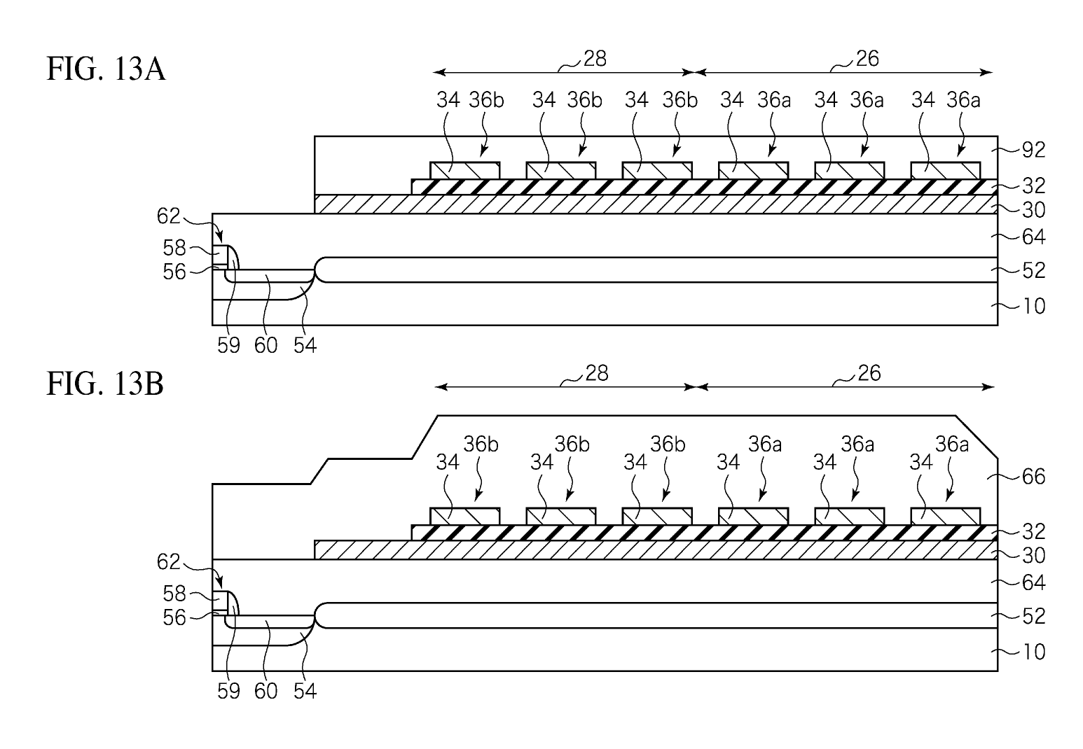

Next, with the photoresist film 92 as the mask, the conducting film 30 is etched. Thus, the lower electrode 30 of the conducting film is formed (see FIG. 13A). Then, the photoresist film 92 is removed.

Thus, in the actually operative capacitor part 26, the actually operative capacitors 36a each comprising the lower electrode 30, the ferroelectric film 32 and the upper electrode 34 are formed, and in the dummy capacitor part 28, the dummy capacitors 36b each comprising the lower electrode 30, the ferroelectric film 32 and the upper electrode 34 are formed.

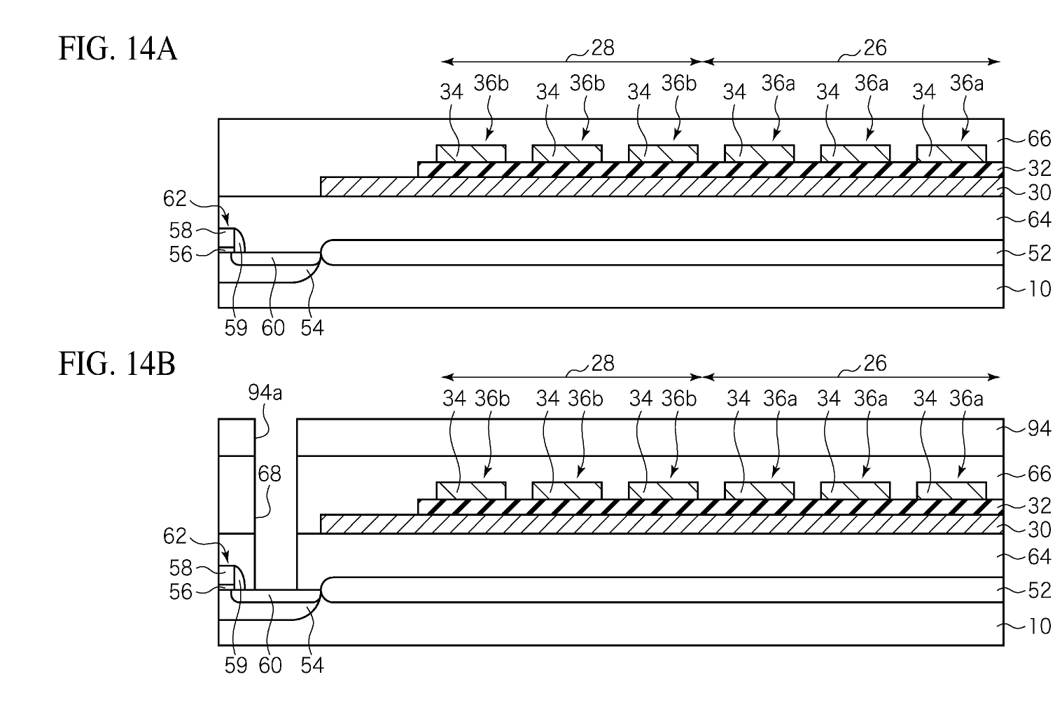

Next, by, e.g., plasma TEOS CVD, silicon oxide film is deposited to form the inter-layer insulating film 66 of the silicon oxide film (see FIG. 13B). Then, the surface of the inter-layer insulating film 66 is planarized by, e.g., CMP (see FIG. 14A).

Then, on the entire surface, a photoresist film 94 is formed by spin coating.

Next, by photolithography, openings 94a for exposing the regions for the contact holes 68 to be formed down to the source/drain regions 60 are formed in the photoresist film 94.

Next, with the photoresist film 94 as the mask, the inter-layer insulating films 66, 64 are etched. Thus, the contact holes 60 are formed down to the source/drain regions 60 (see FIG. 14B). Then, the photoresist film 94 is removed.

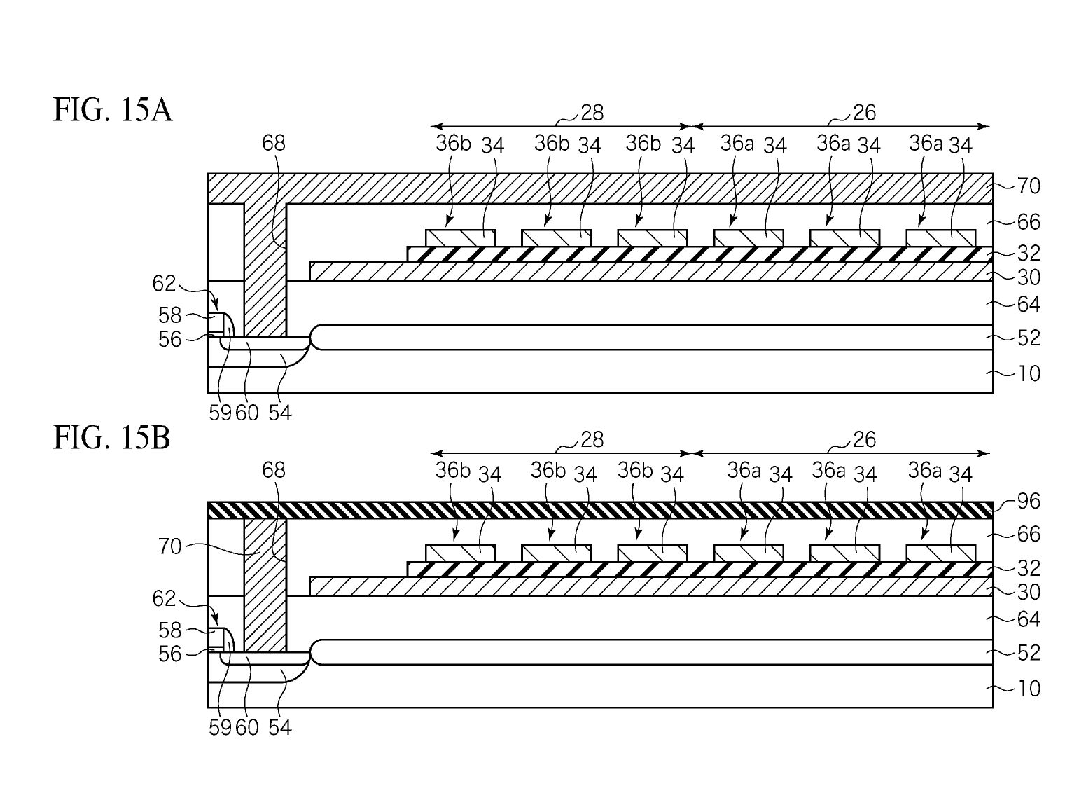

Then, on the entire surface, a tungsten film 70, for example, is deposited by, e.g., CVD (see FIG. 15A).

Then, the tungsten film 70 on the inter-layer insulating film 66 is polished back by, e.g., CMP to form the contact plugs 70 buried in the contact holes 68.

Next, on the entire surface, a silicon oxynitride film (SiON film) 96 is deposited by, e.g., CVD (see FIG. 15B).

Next, on the entire surface, a photoresist film 98 is formed by spin coating.

Then, by photolithography, openings 98a for exposing the regions for the contact holes 38 to be formed down to the upper electrodes 34 and openings 98b for exposing the region for the contact holes 46 to be formed down to the lower electrodes 30 are formed in the photoresist film 98.

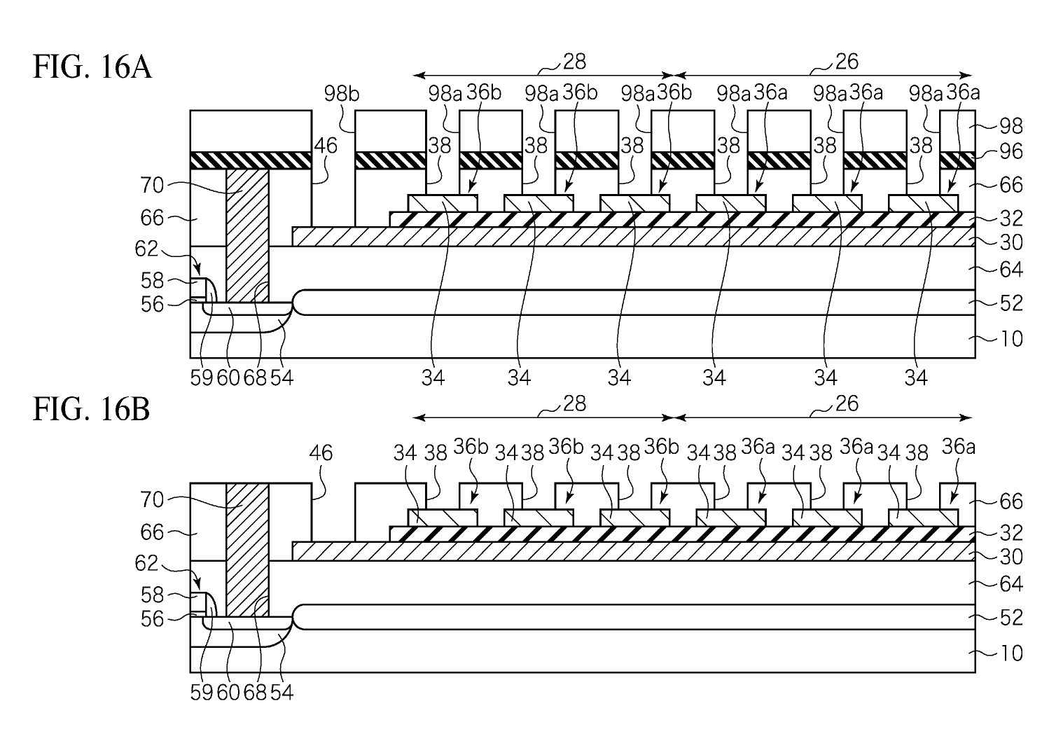

Next, with the photoresist film 98 as the mask, the silicon oxynitride film 96 and the inter-layer insulating film 66 are etched. Thus, in the inter-layer insulating film 66, the contact holes 38 and the contact holes 46 are formed respectively down to the upper electrodes 34 and down to the lower electrodes 30 (see FIG. 16A). Then, the photoresist film 98 is removed.

Then, the silicon oxynitride film 96 is etched back to remove the silicon oxynitride film 96 (see FIG. 16B).

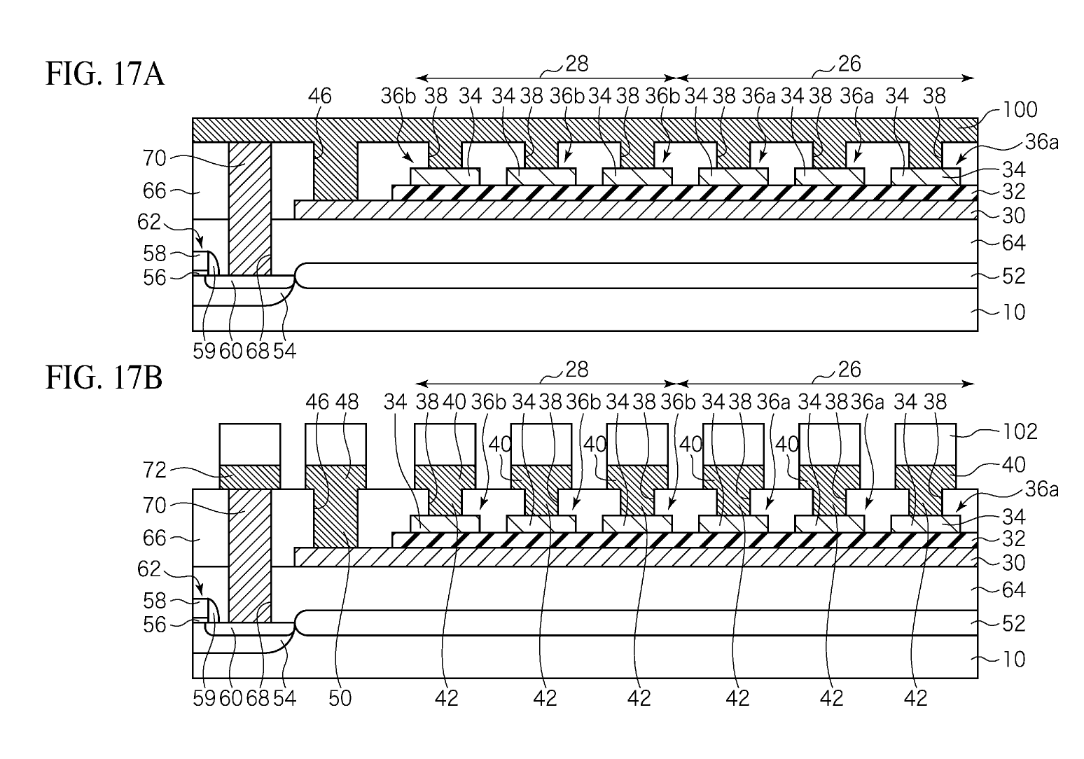

Next, on the inter-layer insulating film 66 with the contact holes 38, 46 formed in, the layer film 100, e.g., of a TiN film, an AlCu alloy film and a TiN film sequentially laid is deposited (see FIG. 17A). The TiN film is formed between the platinum film forming the electrodes and the AlCu film to thereby prevent the reaction between the platinum and aluminum.

Next, on the entire surface, a photoresist film 102 is formed by spin coating.

Then, by photolithography, the photoresist film 102 is patterned into the plane shapes of the interconnections 40, 48, 72.

Next, with the photoresist film 102 as the mask, the layer film 100 is etched. Thus, the interconnections 40, 48, 72 of the layer film 100 are formed (see FIG. 17B). The interconnections 40 in the actually operative capacitor part 26 are connected to the upper electrodes 34 of the actually operative capacitors 36a via the contact holes 38. The interconnections 40 in the dummy capacitor part 28 are connected to the upper electrodes 34 of the dummy capacitors 36b via the contact holes 38. The interconnections 48 are connected to the lower electrodes 30 via the contact holes 46. The interconnections 72 are connected to the contact plugs 70.

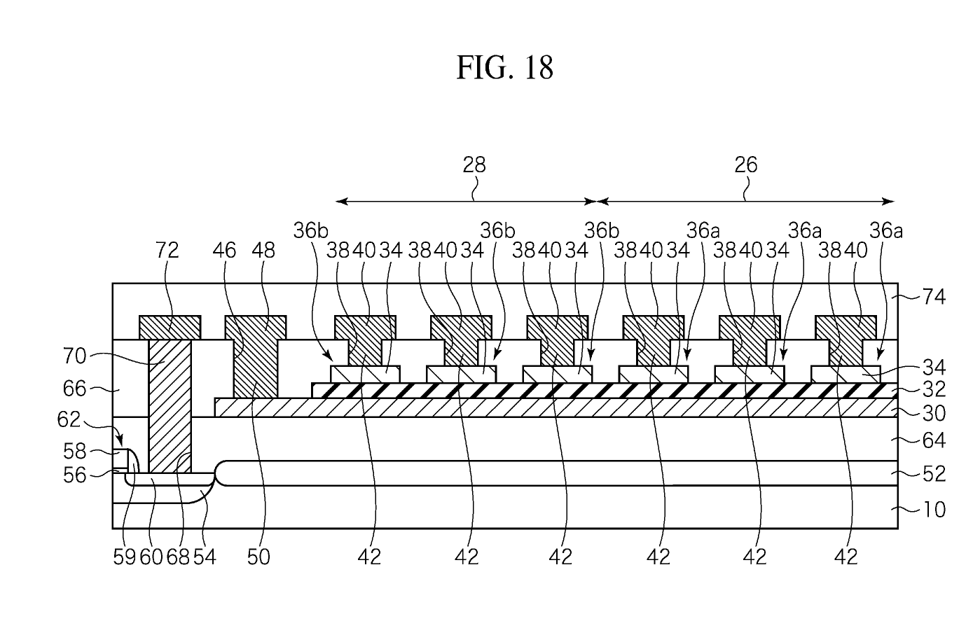

Then, on the entire surface, a silicon oxide film is deposited by, e.g., plasma TEOS CVD to form the inter-layer insulating film 74. Then, the surface of the inter-layer insulating film 74 is planarized by, e.g., CMP (see FIG. 18).

Next, on the entire surface, a photoresist film 104 is deposited by spin coating.

Next, by photolithography, openings 104a for exposing the regions for the contact holes 76 to be formed down to the interconnections 40 in the actually operative capacitor part 26 and openings 104b for exposing the regions for the contact holes 80 to be formed down to the interconnections 48 and openings 104c for exposing the regions to be formed down to the interconnections 72 are formed in the photoresist film 104. The photoresist film 104 is left on the dummy capacitor part 28.

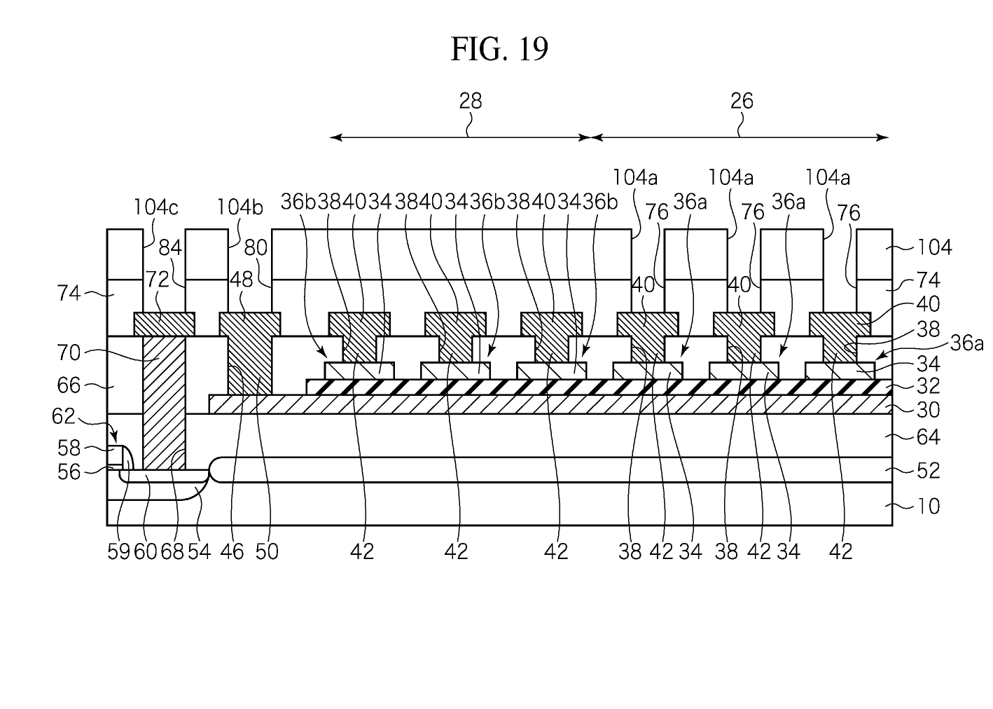

Then, with the photoresist film 104 as the mask, the inter-layer insulating film 74 is etched. Thus, in the inter-layer insulating film 74, the contact holes 76, the contact holes 80 and the contact holes 84 are formed respectively down to the interconnections 40 in the actually operative capacitor part 26, the interconnections 48 and the interconnections 72 (see FIG. 19). Then, the photoresist film 104 is removed.

Next, on the entire surface, a tungsten film, for example, is deposited by, e.g., CVD, and then the tungsten film on the inter-layer insulating film 74 is polished back by, e.g., CMP to form the contact plugs 78, the contact plugs 82 and the contact plugs 84 buried respectively in the contact holes 78, the contact holes 80 and the contact holes 84. In the actually operative capacitor part 26, the contact plugs 78 are formed, connected to the interconnections 40, but in the dummy capacitor part 28, no contact plugs are formed, connected to the interconnections 40. Accordingly, in the dummy capacitor part 28, the interconnections 40 connected to the upper electrodes 34 of the dummy capacitors 36b are electrically isolated from the other interconnections.

Then, on the inter-layer insulating film 74, interconnection layers are formed suitably corresponding to a design of the FeRAM, and the semiconductor device according to the present embodiment is completed.

### A Second Embodiment

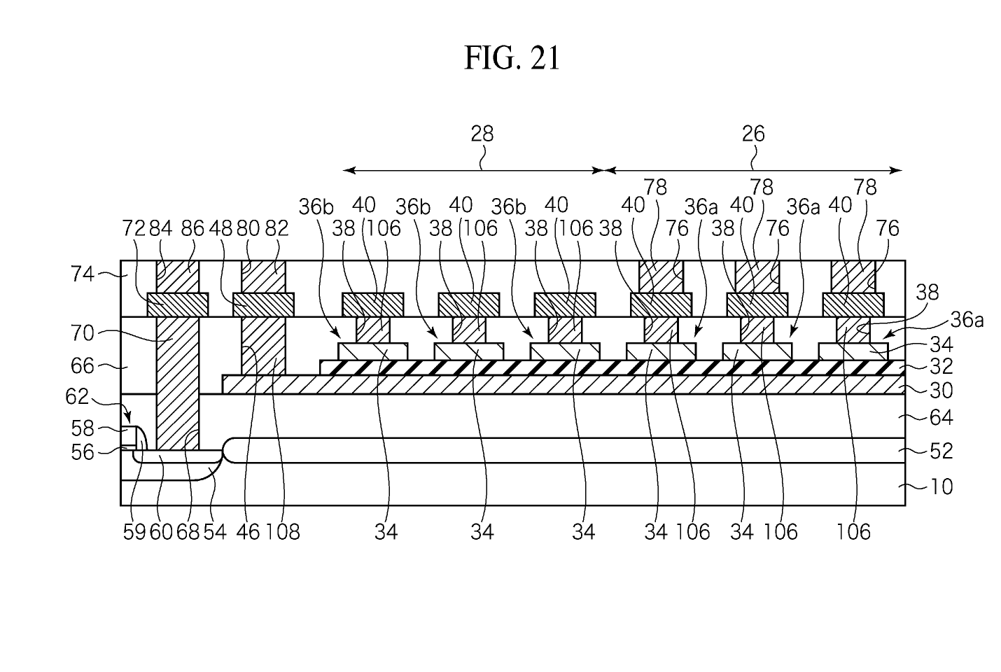

The semiconductor device and the method of manufacturing the same according to a second embodiment will be explained with reference to FIGS. 21 to 23. The same members of the present embodiment as those of the semiconductor device and the method of manufacturing the same according to the first embodiment are represented by the same reference numbers not to repeat or to simplify their explanation.

The basic structure of the semiconductor device according to the present embodiment is substantially the same as that of the semiconductor device according to the first embodiment. The semiconductor device according to the present embodiment is different from the semiconductor device according to the first embodiment in that in the former, the interconnection 40 formed over the upper electrode 34, and the contact plug 106 interconnecting the interconnection 40 and the upper electrode 34 are formed independently of each other.

Then, the structure of the semiconductor device according to the present embodiment will be explained with reference to FIG. 21. FIG. 21 is a sectional view showing the structure of the semiconductor device according to the present embodiment.

In an inter-layer insulating film 66 in an actually operative capacitor part 26, contact holes 38 are formed down to the upper electrodes 34 of actually operative capacitors 36a. In the inter-layer insulating film 66 in a dummy capacitor part 28, contact holes 38 are formed down to the upper electrodes 34 of dummy capacitors 36b.

In the inter-layer insulating film 66, the contact holes 46 are formed down to the lower electrodes 30.

In the contact holes 38 in the actually operative capacitor part 26, the contact plugs 106 are buried, connected to the upper electrodes 34 of the actually operative capacitors 36a. In the contact holes 38 in the dummy capacitor part 28, the contact plugs 106 connected to the upper electrodes 34 of the dummy capacitors 36b are buried.

In the contact holes 46, the contact plugs 108 are buried, connected to the lower electrodes 30.

On the contact plugs 106 and the inter-layer insulating film 66 in the actually operative capacitor part 26, the interconnections 40 are formed, connected to the contact plugs 106.

Similarly, on the contact plugs 106 and the inter-layer insulating film 66 in the dummy capacitor part 28, the interconnections 40 are formed, connected to the contact plugs 106.

As in the semiconductor device according to the first embodiment, the interconnections 40 connected to the upper electrodes 34 of the actually operative capacitors 36a via the contact plugs 106 and the interconnections 40 connected to the upper electrodes 34 of the dummy capacitors 36b via the contact plugs 106 have the same plane shape and the same area, and are arranged at the same pitch. The contact plugs 106 connected to the upper electrodes 34 of the actually operative capacitors 36a and the contact plugs 106 connected to the upper electrodes 34 of the dummy capacitors 36b have the same plane shape and the same area, and are arranged at the same pitch. The contact plugs 106 have a rectangular plane shape.

On the contact plugs 108 and the inter-layer insulating film 66, the interconnections 48 are formed, connected to the contact plugs 108.

As described above, the interconnection 40 formed on the upper electrode 34 and the contact plug 106 interconnecting the interconnection 40 and the upper electrode 34 may be formed independent of each other.

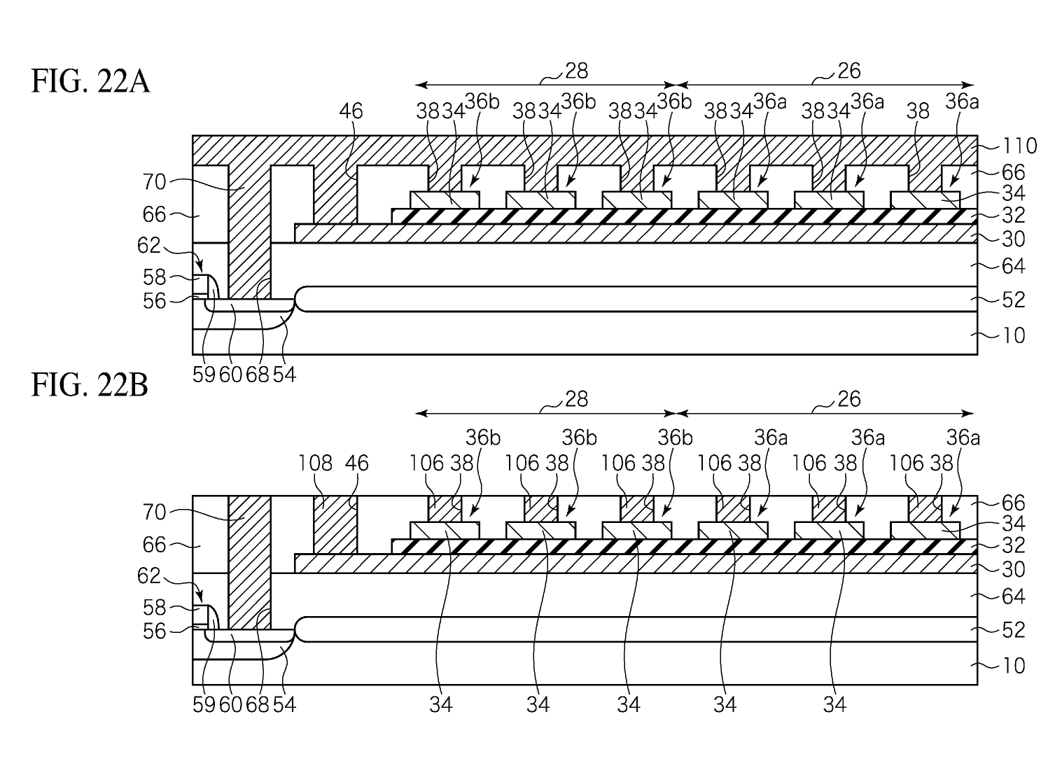

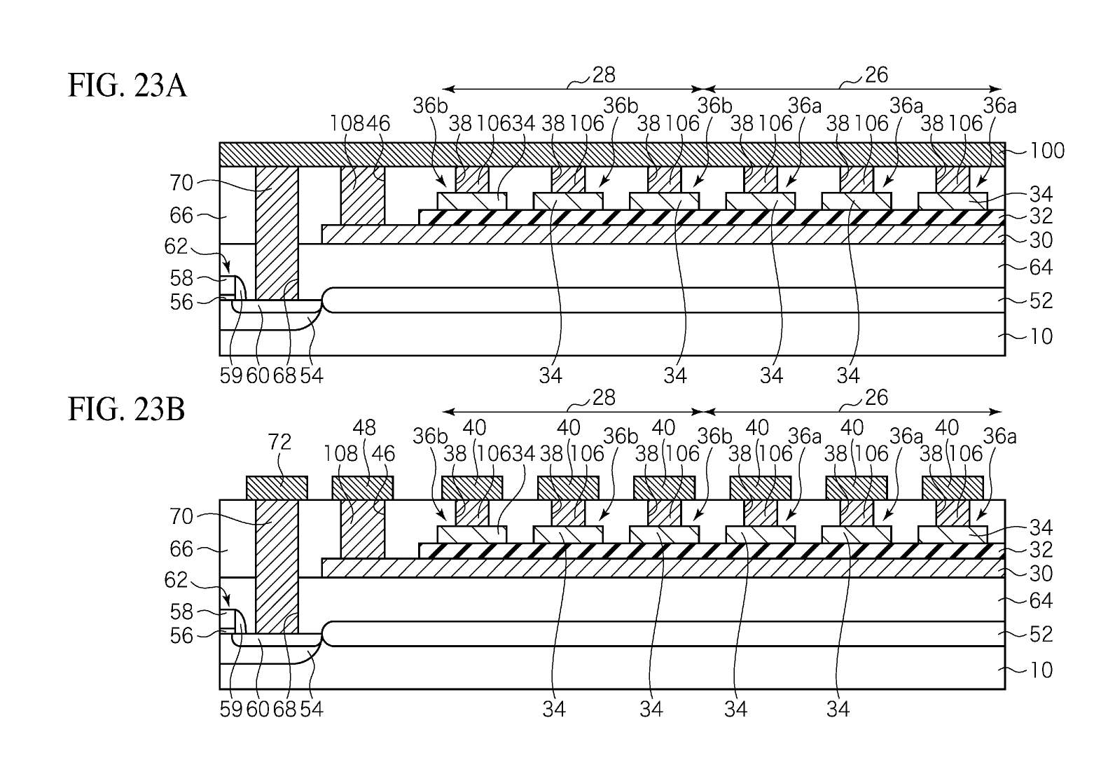

Next, the method of manufacturing the semiconductor device according to the present embodiment will be explained with reference to FIGS. 22 and 23. FIGS. 22 and 23 are sectional views showing the method of manufacturing the semiconductor device according to the present embodiment.

First, in the same way as in the method of manufacturing the semiconductor device shown in FIGS. 11A to 16B, the members up to the contact holes 38, 46 are formed.

Next, on the inter-layer insulating film 66 with the contact holes 38, 46 formed in, a tungsten film 110, for example, is deposited by, e.g., CVD (see FIG. 22A).

Next, by, e.g., CMP, the tungsten film 110 on the inter-layer insulating film 66 is polished back to form the contact plugs 106 buried in the contact holes 38 and the contact plugs 108 buried in the contact holes 46 (see FIG. 22B).

Then, on the inter-layer insulating film 66 with the contact plugs 106, 108 buried in, the layer film 100, e.g., of a TiN film, an AlCu alloy film and a TiN film sequentially laid is deposited by, e.g., sputtering (see FIG. 23A).

Next, by photolithograph and dry etching, the layer film 100 is patterned. Thus, the interconnections 40, 48, 72 of the layer film 100 are formed (see FIG. 23B). The interconnections 40 in the actually operative capacitor part 26 are connected to the upper electrodes 34 of the actually operative capacitors 36a via the contact plugs 106. The interconnections 40 in the dummy capacitor part 28 are connected to the upper electrodes 34 of the dummy capacitors 36b via the contact plugs 106. The interconnections 48 are connected to the lower electrodes 30 via the contact plugs 108.

The following steps are the same as those of the method for manufacturing the semiconductor device according to the first embodiment shown in FIGS. 18 to 20, and their explanation will not be repeated.

### A Third Embodiment

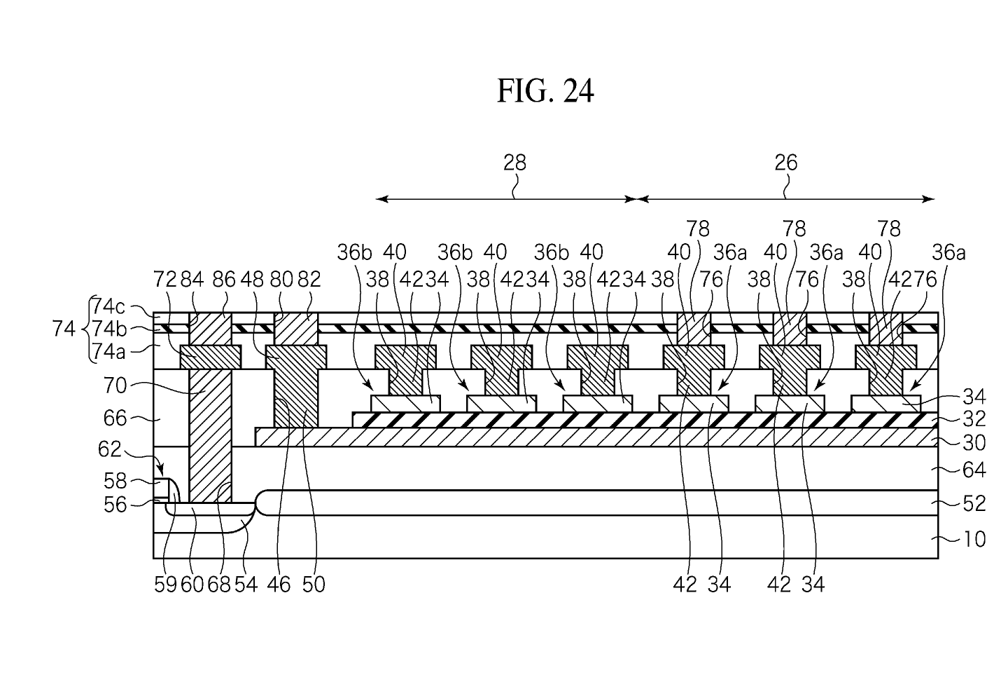

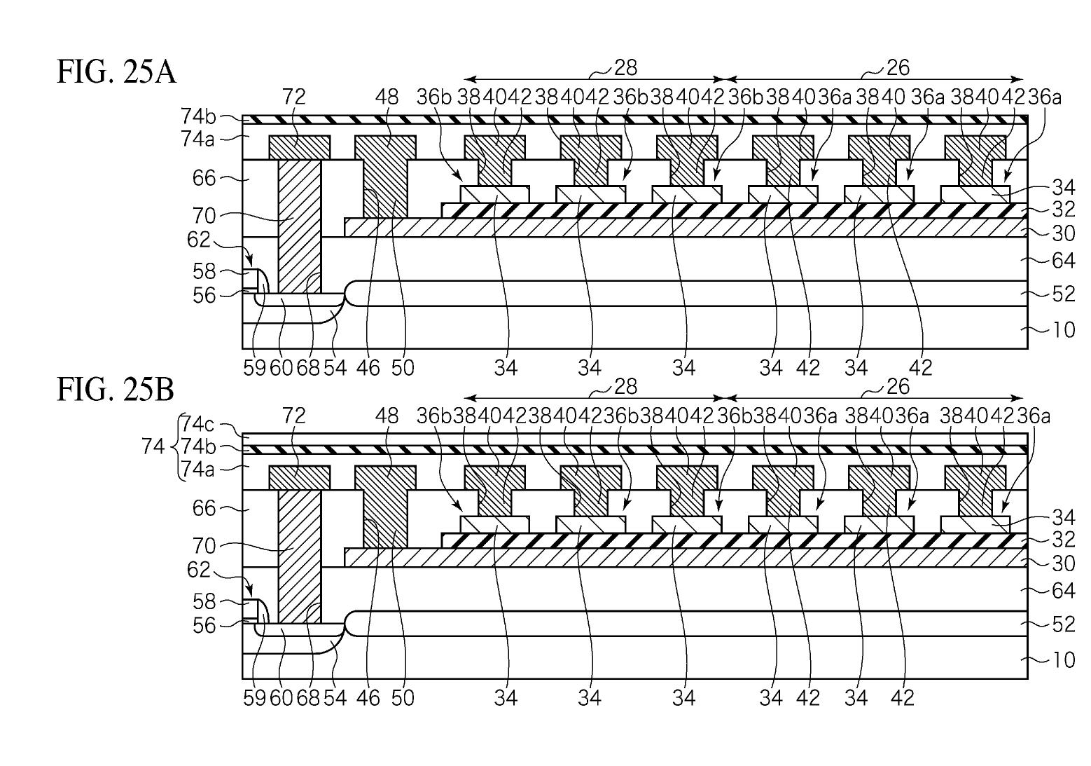

The semiconductor device and the method of manufacturing the same according to a third embodiment will be explained with reference to FIGS. 24 and 25. The same members of the present embodiment as those of the semiconductor device and the method of manufacturing the same according to the first and the second embodiments are represented by the same reference numbers not to repeat or to simplify their explanation.

The basic structure of the semiconductor device according to the present embodiment is substantially the same as that of the semiconductor device according to the first embodiment. The semiconductor device according to the present embodiment is different from the semiconductor device according to the first embodiment in that in the former, the inter-layer insulating film 74 is formed of the layer film of an insulation film 74a, a hydrogen/water diffusion preventing film 74b and an insulation film 74c sequentially laid.

The structure of the semiconductor device according to the present embodiment will be explained with reference to FIG. 24. FIG. 24 is a sectional view showing the structure of the semiconductor device according to the present embodiment.

On an inter-layer insulating film 66 with interconnections 40, 48, 72 formed on, the insulation film 74a of a silicon oxide film is formed. The surface of the insulating film 74a is planarized.

On the insulation film 74a, the hydrogen/water diffusion preventing film 74b is formed. As the hydrogen/water diffusion preventing film 74b, an aluminum oxide film, for example, is used. The hydrogen/water diffusion preventing film 74b is not essentially the aluminum oxide film. Film having the function of preventing the diffusion of hydrogen and water can be used suitably as the hydrogen/water diffusion preventing film.

On the hydrogen/water diffusion preventing film 74b, the insulation film 74c of a silicon oxide film is formed.

Thus, on the inter-layer insulating film 66 with the interconnections 40, 48, 72 formed on, the inter-layer insulating film 74 of the layer film of the insulation film 74a, the hydrogen/water diffusion preventing film 74b and the insulation film 74c sequentially laid is formed.

As described above, the semiconductor device according to the present embodiment is characterized in that the hydrogen/water diffusion preventing film 74b is formed over the actually operative capacitors 36a and the dummy capacitors 36b.

The hydrogen/water diffusion preventing film 74b is formed, whereby the volume of the insulation film, such as silicon oxide film or others, which is highly hydrophilic, used as the inter-layer insulating film 74 can be decreased. Accordingly, the hydrogen/water residual amounts in the inter-layer insulating film 74 above the actually operative capacitors 36a and the dummy capacitors 36b can be decreased. The hydrogen/water diffusion preventing film 74b can prevent the arrival of hydrogen and water at the ferroelectric film 72 from above. Thus, the performance deterioration of the actually operative capacitors 36a due to hydrogen and water can be further surely suppressed, and the lifetime characteristics of the FeRAM can be further improved.

Then, the method of manufacturing the semiconductor device according to the present embodiment will be explained with reference to FIG. 25. FIG. 25 is sectional views showing the method of manufacturing the semiconductor device according to the present embodiment.

First, in the same way as in the method of manufacturing the semiconductor device illustrated in FIGS. 11A to 17B, the members up to the interconnections 40, 48, 72 are formed, and the photoresist film 102 used as the mask is removed.

Next, on the entire surface, the insulation film 74a of a silicon oxide film is deposited by, e.g., CVD. Then, the surface of the insulation film 74a is planarized by, e.g., CMP.

Next, on the insulation film 74a, the hydrogen/water diffusion preventing film 74b is formed by, e.g., sputtering or CVD (see FIG. 25A). As the hydrogen/water diffusion preventing film 74b, an aluminum oxide film, for example, is formed.

Next, on the hydrogen/water diffusion preventing film 74b, the insulation film 74c of a silicon oxide film is deposited by, e.g., CVD.

Thus, the inter-layer insulating film 74 of the insulation film 74a, the hydrogen/water diffusion preventing film 74b and the insulation film 74c sequentially laid is formed (see FIG. 25B).

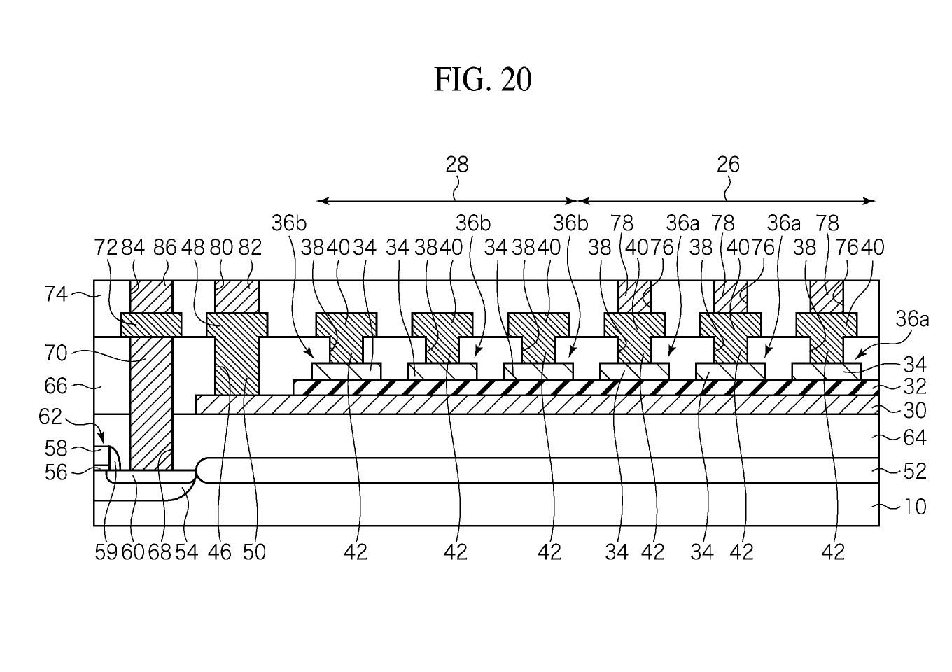

The following steps are the same as those of the method of manufacturing the semiconductor device according to the first embodiment illustrated in FIGS. 19 and 20, and their explanation will not be repeated.

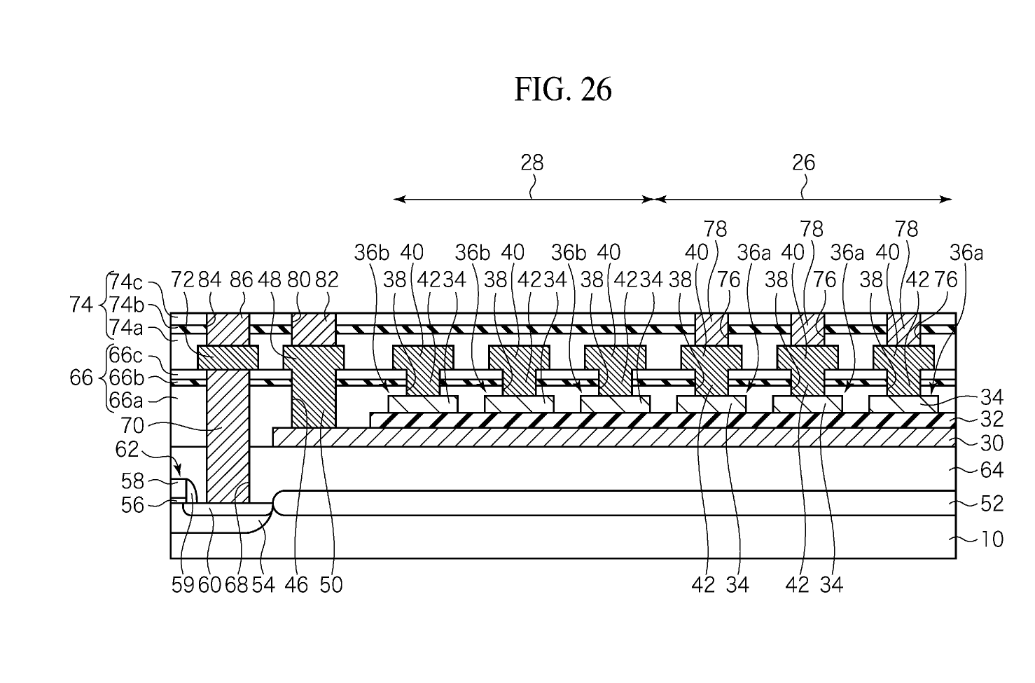

In the present embodiment, the hydrogen/water diffusion preventing film 74b is formed over the interconnections 40, 48, 72, but further between the upper electrodes 34 and the interconnections 40, the same hydrogen/water diffusion preventing film 66b as the hydrogen/water diffusion preventing film 74b may be formed. That is, as shown in FIG. 26, the inter-layer insulating film 66 is formed of the layer film of an insulation film 66a, the hydrogen/water diffusion preventing film 68b and an insulation film 66c sequentially laid to thereby form the hydrogen/water diffusion preventing film 66b further between the upper electrodes 34 and the interconnections 40. Thus, the plural layers of the hydrogen/water diffusion preventing films 66b, 74b are formed on the actually operative capacitors 36a and dummy capacitors 36b, whereby the performance deterioration of the actually operative capacitors 36a due to hydrogen and water can be further surely suppressed, and the lifetime characteristics of the FeRAM can be further improved. Without forming the hydrogen/water diffusion preventing film 74b, the hydrogen/water diffusion preventing film 66b may be formed.

In the present embodiment, the hydrogen/water diffusion preventing film 74b is formed in the semiconductor device according to the first embodiment shown in FIG. 6. In the semiconductor device according to the second embodiment as well, the hydrogen/water diffusion preventing film 74b may be formed.

### A Fourth Embodiment

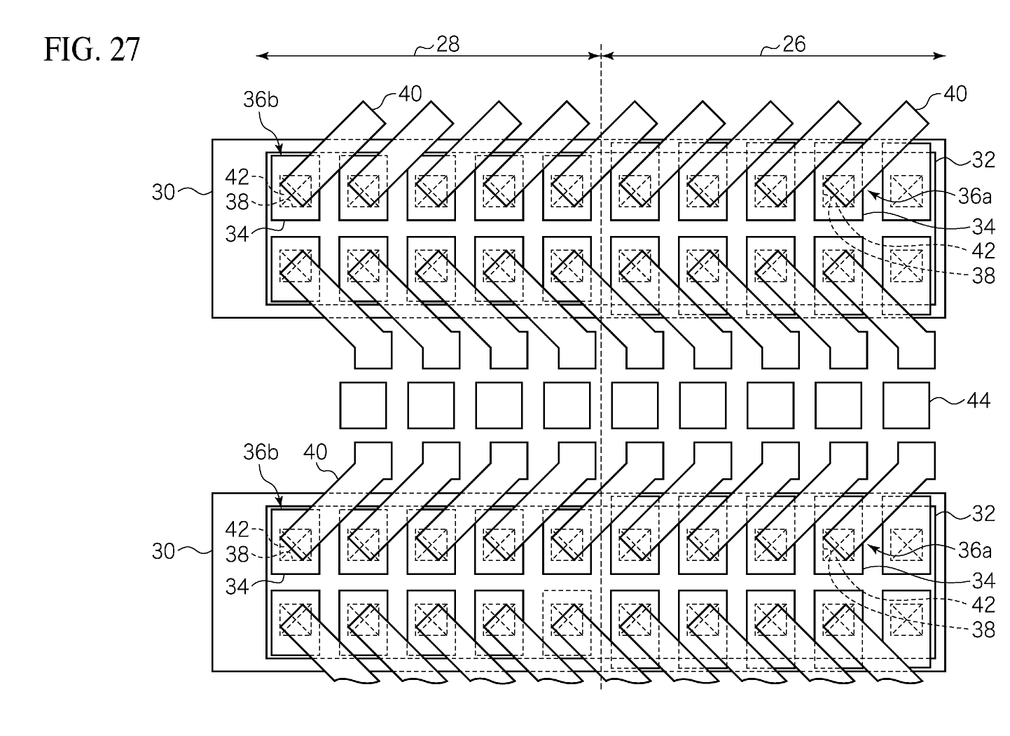

The semiconductor device according to a fourth embodiment will be explained with reference to FIG. 27. The same members of the present embodiment as those of the semiconductor device according to the first to the third embodiments are represented by the same reference number not to repeat or to simplify their explanation.

The basic structure of the semiconductor device according to the present embodiment is substantially the same as that of the semiconductor device according to the first embodiment. The semiconductor device according to the present embodiment is different from the semiconductor device according to the first embodiment in that in the former, the interconnections 40 in the actually operative capacitor part 26 and the interconnections 40 in the dummy capacitor part 28 are tilted in the same direction and at the same angle with respect to the arrangement direction of the actually operative capacitors 36a and the dummy capacitors 36b.

The structure of the semiconductor device according to the present embodiment will be explained with reference to FIG. 27. FIG. 27 is a plan view showing the structure of the semiconductor device according to the present embodiment.

As shown, as in the semiconductor device according to the first embodiment shown in FIG. 5, in an actually operative capacitor part 26, actually operative capacitors 36a each including a lower electrode 30, a ferroelectric film 32 and an upper electrode 34 are formed. In a dummy capacitor part 28, dummy capacitors 36b each including a lower electrode 30, a ferroelectric film 32 and an upper electrode 34 are formed. The actually operative capacitors 36a and the dummy capacitors 36 have the substantially same plane shape and the substantially same area, and are arranged at the substantially same pitch.

The interconnections 40 connected to the upper electrodes 34 of the actually operative capacitors 36a have a rectangular plane shape and are arranged with the longer directions tilted at a prescribed angle to the arrangement direction (the transverse direction as viewed in the drawing) of the actually operative capacitors 36a and the dummy capacitors 36b.

The interconnections 40 connected to the upper electrodes 34 of the dummy capacitors 36b also have a rectangular plane shape and are arranged with the longer directions tilted at the prescribed angle to the arrangement direction (the transverse direction as viewed in the drawing) of the actually operative capacitors 36a and the dummy capacitors 36b. The title direction and the tilt angle of the interconnections 40 connected to the upper electrodes 34 of the dummy capacitors 36b are the same as those of the interconnections 40 connected to the upper electrodes 34 of the actually operative capacitors 36a.

As described above, the interconnections 40 in the actually operative capacitor part 26 and the interconnections 40 in the dummy capacitor part 28 may be tilted in the same direction and at the same angle with respect to the arrangement direction of the actually operative capacitors 36a and the dummy capacitors 36b.

### A Fifth Embodiment

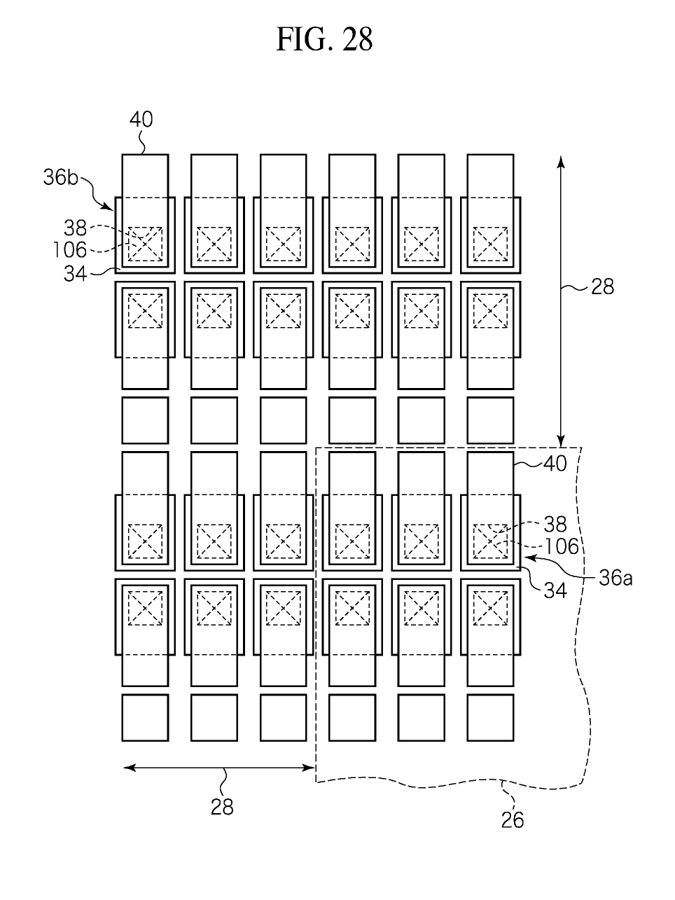

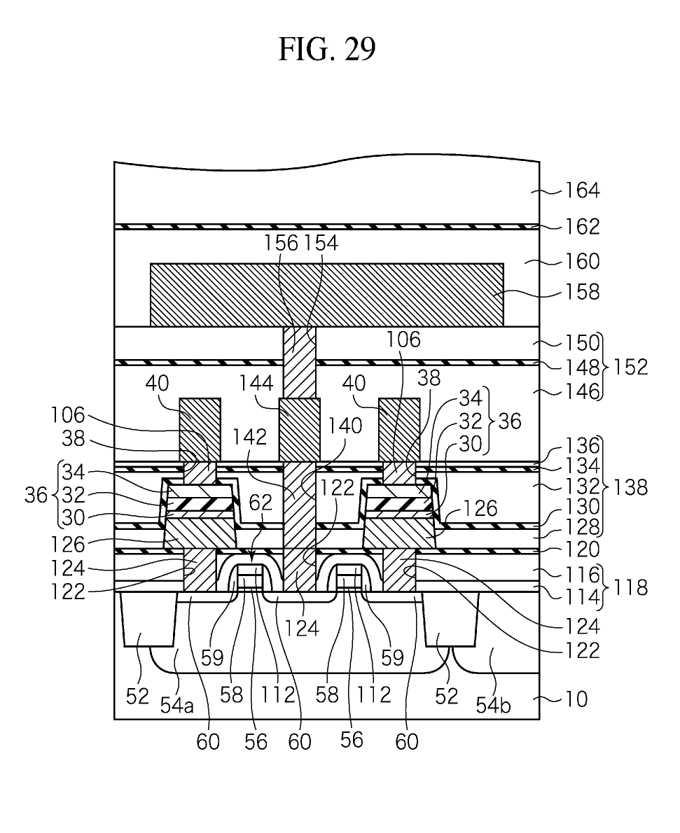

The semiconductor device according to a fifth embodiment will be explained with reference to FIGS. 28 and 29. The same members of the present embodiment as those of the semiconductor device according to the first to the fourth embodiments are represented by the same reference numbers not to repeat or to simplify their explanation.

In the semiconductor device according to the first to the fourth embodiments, the actually operative capacitors 36a and the dummy capacitors 36b are the planar-type ferroelectric capacitors. In the semiconductor device according to the present embodiment, however, the actually operative capacitors 36a and the dummy capacitors 36b are stack-type ferroelectric capacitors.

The structure of the semiconductor device according to the present embodiment will be explained with reference to FIGS. 28 and 29. FIG. 28 is a plan view showing the structure of the semiconductor device according to the present embodiment. FIG. 29 is a sectional view showing the structure of the semiconductor device according to the present embodiment.

As illustrated in FIG. 28, in the actually operative capacitor part 26, stack-type actually operative capacitors 36a are arranged. In the dummy capacitor part 28 enclosing the actually operative capacitor part 26, stack-type dummy capacitors 36b are arranged. The actually operative capacitors 36a and the dummy capacitors 36b have the same plane shape and the same area, and are arranged at the same pitch.

Over the actually operative capacitors 36a, interconnections 40 are formed, connected to the upper electrodes 34 of the actually operative capacitors 36a via contact holes 38 formed in an inter-layer insulating film. In the contact holes 38, contact plugs 106 for connecting the interconnections 40 and the upper electrodes 34 to each other are buried.

Similarly, over the dummy capacitors 36b, interconnections 40 are formed, connected to the upper electrodes 34 of the dummy capacitors 36b via contact holes 38 formed in the inter-layer insulating film. In the contact holes 38, contact plugs 106 for connecting the interconnections 40 and the upper electrodes 34 to each other are buried.

The interconnections 40 formed over the actually operative capacitors 36a and the interconnections 40 formed over the dummy capacitors 36b have the same plane shape and the same area, and are arranged at the same pitch. The contact plugs 106 connected to the upper electrodes 34 of the actually operative capacitors 36a and the contact plugs 106 connected to the upper electrodes 34 of the dummy capacitors 36b have the same plane shape and the same area, and are arranged at the same pitch.

Then, the structure of the stack-type ferroelectric capacitor 36 forming the actually operative capacitor 36a and the dummy capacitor 36b will be explained with reference to FIG. 29.

As illustrated, in a semiconductor substrate 10 of, e.g., silicon, a device isolation region 52 for defining a device region is formed. In the semiconductor substrate 10 with the device isolation regions 52 formed in, wells 54a, 54b are formed.

On the semiconductor substrate 10 with the wells 54a, 54b formed in, gate electrodes 58 are formed with a game insulation film 56 formed therebetween. On the gate electrodes 58, silicon oxide films 112 are formed. On the side wall of the gate electrode 58 and the silicon oxide film 112, a sidewall insulation film 59 is formed. On both sides of each gate electrode 58, source/drain regions 60 are formed. Thus, transistors 62 each including the gate electrode 58 and the source/drain regions 60 are formed on the semiconductor substrate 10.

On the semiconductor substrate 10 with the transistors 62 formed on, an inter-layer insulating film 118 of a silicon oxynitride film 114 and a silicon oxide film 116 sequentially laid is formed. The surface of the inter-layer insulating film 118 is planarized.

On the inter-layer insulating film 118, a hydrogen/water diffusion preventing film 120 having the function of preventing the diffusion of water and hydrogen is formed.

In the hydrogen/water diffusion preventing film 120 and the inter-layer insulating film 118, contact holes 122 are formed down to the source/drain regions 60.

In the contact holes 122, contact plugs 124 of tungsten are buried.

On the hydrogen/water diffusion preventing film 120, iridium film 126 is formed, electrically connected to the contact plug 124.

On the iridium film 126, the lower electrode 30 of the ferroelectric capacitor 36 is formed.

On the lower electrode 30, the ferroelectric film of the ferroelectric capacitor 36 is formed. The ferroelectric film 32 is, e.g., a PZT film.

On the ferroelectric film 32, the upper electrode 34 of the ferroelectric capacitor 36 is formed.

The upper electrode 34, the ferroelectric film 32, the lower electrode 30 and the iridium film 126, which are laid the former on the latter, are at once patterned by etching and have the substantially same plane shape.

Thus, the stack-type ferroelectric capacitors 36 each comprising the lower electrode 30, the ferroelectric film 32 and the upper electrode 34 are formed. The lower electrode 30 of the ferroelectric capacitor 36 is electrically connected to the contact plug 124 via the iridium film 126.

In the region where the iridium film 126 is not formed on the inter-layer insulating film 118, a silicon oxynitride film 128 of a film thickness which is substantially the same as that of the iridium film 126 or smaller than that of the iridium film 126 is formed. In place of the silicon oxynitride film 128, silicon oxide film may be formed.

On the ferroelectric capacitors 36 and the silicon oxynitride film 128, a hydrogen/water diffusion preventing film 130 having the function of preventing the diffusion of water and hydrogen is formed. The hydrogen/water diffusion preventing film 130 is, e.g., an aluminum oxide film.

On the hydrogen/water diffusion preventing film 130, a silicon oxide film 132 is formed, burying the ferroelectric capacitors 36. The surface of the silicon oxide film 132 is planarized.

On the planarized silicon oxide film 132, a flat hydrogen/water diffusion preventing film 134 having the function of preventing the diffusion of water and hydrogen is formed. The hydrogen/water diffusion preventing film 134 is, e.g., an aluminum oxide film.

On the hydrogen/water diffusion preventing film 134, a silicon oxide film 136 is formed.

Thus, the silicon oxynitride film 128, the hydrogen/water diffusion preventing film 130, the silicon oxide film 132, the hydrogen/water diffusion preventing film 134 and the silicon oxide film 136 form an inter-layer insulating film 138.

In the silicon oxide film 136, the hydrogen/water diffusion preventing film 134, the silicon oxide film 132 and the hydrogen/water diffusion preventing film 130, contact holes 38 are formed down to the upper electrodes 34 of the ferroelectric capacitors 36. In the silicon oxide film 136, the hydrogen/water diffusion preventing film 134, the silicon oxide film 132, the hydrogen/water diffusion preventing film 130 and the silicon oxynitride film 128, a contact hole 140 is formed down to the contact plug 124.

In the contact holes 38, contact plugs 106 are buried, connected to the upper electrodes 34 of the ferroelectric capacitors 36. In the contact hole 140, a contact plug 142 is buried, connected to the contact plug 124.

On the silicon oxide film 136, interconnections 40 connected to the contact plugs 106 and an interconnection 144 connected to the contact plug 142 are formed.

On the silicon oxide film 136 with the interconnections 40, 144 formed on, a silicon oxide film 146 is formed, burying the interconnections 40, 144. The surface of the silicon oxide film 146 is planarized.

On the planarized silicon oxide film 146, a flat hydrogen/water diffusion preventing film 148 having the function of preventing the diffusion of water and hydrogen is formed. The hydrogen/water diffusion preventing film 148 is, e.g., an aluminum oxide film.

On the hydrogen/water diffusion preventing film 148, a silicon oxide film 150 is formed.

Thus, the silicon oxide film 146, the hydrogen/water diffusion preventing film 148 and the silicon oxide film 150 form the inter-layer insulating film 152.

In the silicon oxide film 150, the hydrogen/water diffusion preventing film 148 and the silicon oxide film 146, a contact hole 154 is formed down to the interconnection 144.

In the contact hole 154, a contact plug 156 is buried, connected to the interconnection 144.

On the silicon oxide film 150, an interconnection 158 is formed, connected to the contact plug 156.

On the silicon oxide film 150 with the interconnection 158 formed on, a silicon oxide film 160 is formed, burying the interconnection 158. The surface of the silicon oxide film 160 is planarized.

On the planarized silicon oxide film 160, a hydrogen/water diffusion preventing film 162 having the function of preventing the diffusion of water and hydrogen is formed. The hydrogen/water diffusion preventing film 162 is, e.g., an aluminum oxide film.

On the hydrogen/water diffusion preventing film 162, a silicon oxide film 164 is formed.

Upper of the silicon oxide film 164, interconnection layers are formed suitably corresponding to a design of the FeRAM.

The actually operative capacitors 36a and the dummy capacitors 36b may be formed of such stack-type ferroelectric capacitors 36.

### Modified Embodiments

The present invention is not limited to the above-described embodiments and can cover other various modifications.

For example, in the above-described embodiments, the dummy capacitor part 28 is provided in the memory cell region 16, but the dummy capacitor part 28 may be provided in a region other than the memory cell region 16. For example, the same dummy capacitor part 28 as described above may be provided in the logic circuit region 20, the peripheral circuit regions 18, 22 or others.

In the above-described embodiments, the pitch of the dummy capacitors 36b is the same as that of the actually operative capacitors 36a. The pitch of the dummy capacitors 36b may not be essentially the same as that of the actually operative capacitors 36a. For example, the ratio of the pitch of the dummy capacitors 36b to the pitch of the actually operative capacitors 36a may be in a range of 0.9-1.1.

In the above-described embodiments, the area of the dummy capacitor 36b is the same as that of the actually operative capacitor 36a. However, the area of the dummy capacitor 36b may not be essentially the same as the area of the actually operative capacitor 36a. For example, the ratio of the area of the dummy capacitor 36b to the area of the actually operative capacitor 36a may be in a range of 0.9-1.1.

In the above-described embodiments, the plane shapes of the actually operative capacitor 36a and the dummy capacitor 36b are rectangular, but the plane shapes of the actually operative capacitor 36a and the dummy capacitor 36b are not essentially rectangular. The plane shapes of the actually operative capacitor 36a and the dummy capacitor 36b may be polygonal, such as hexagonal or others, or circular.

In the above-described embodiments, the pitch of plug portions 42 or the contact plugs 106 in the dummy capacitor part 28 is the same as that of the plug portions 42 or the contact plugs 106 in the actually operative capacitor part 26. However, the pitch of the plug portions 42 or the contact plugs 106 in the dummy capacitor part 28 may not be essentially the same as that of the plug portions 42 or the contact plugs 106 in the actually operative unit 26. For example, the ratio of the pitch of the plug portions 42 or the contact plugs 106 in the dummy capacitor part 28 to the pitch of the plug portions 42 or the contact plugs 106 in the actually operative capacitor part 26 may be in a range of 0.9-1.1.

In the above-described embodiments, the area of the plug portion 42 or the contact plug 106 in the dummy capacitor part 28 is the same as that of the plug portion 42 or the contact plug 106 in the actually operative capacitor part 26. However, the area of the plug portion 42 or the contact plug 106 in the dummy capacitor part 28 may not be essentially the same as that of the plug portion 42 or the contact plug 106 in the actually operative capacitor part 28. For example, the ratio of the area of the plug portion 42 or the contact plug 106 in the dummy capacitor part 28 to the area of the plug portion 42 or the contact plug 106 in the actually operative capacitor part 26 may be in a range of 0.9-1.1.

In the above-described embodiments, the plane shapes of the plug portions 42 or the contact plugs 106 in the actually operative capacitor part 26 and the dummy capacitor part 28 are rectangular. However, the plane shapes of the plug portions 42 or the contact plugs 106 are not essentially rectangular. The plane shape of the plug portions 42 or the contact plugs 106 may be, e.g., polygonal, such as hexagonal or others, or circular.

In the above-described embodiments, the pitch of the interconnections 40 in the dummy capacitor part 28 is the same as that of the interconnections 40 in the actually operative capacitor part 26. However, the pitch of the interconnections 40 in the dummy capacitor part 28 may not be essentially the same as that of the interconnections 40 in the actually operative capacitor part 26. For example, the ratio of the pitch of the interconnections 40 in the dummy capacitor part 28 to the pitch of the interconnections 40 in the actually operative capacitor part 26 may be in a range of 0.9-1.1.

In the above-described embodiments, the area of the interconnection 40 in the dummy capacitor part 28 is the same as that of the interconnection 40 in the actually operative capacitor part 26. However, the area of the interconnection 40 in the dummy capacitor part 28 may not be essentially the same as that of the interconnection 40 in the actually operative capacitor part 26. For example, the ratio of the area of the interconnection 40 in the dummy capacitor part 28 to the area of the interconnection 40 in the actually operative capacitor part 26 may be in a range of 0.9-1.1.

In the above-described embodiments, the plane shapes of the interconnections 40 in the actually operative capacitor part 26 and the dummy capacitor part 28 are rectangular, but the plane shapes of the interconnections 40 are not essentially rectangular. The plane shape of the interconnections 40 may be polygonal, such as hexagonal or others, or circular.

In the above-described embodiments, as exemplified in FIGS. 3 to 5, the arrangement of the dummy capacitors 36b is in alignment with the arrangement of the actually operative capacitors 36a. However, the arrangement of the dummy capacitors 36b may not be essentially in alignment with the arrangement of the actually operative capacitors 36a.

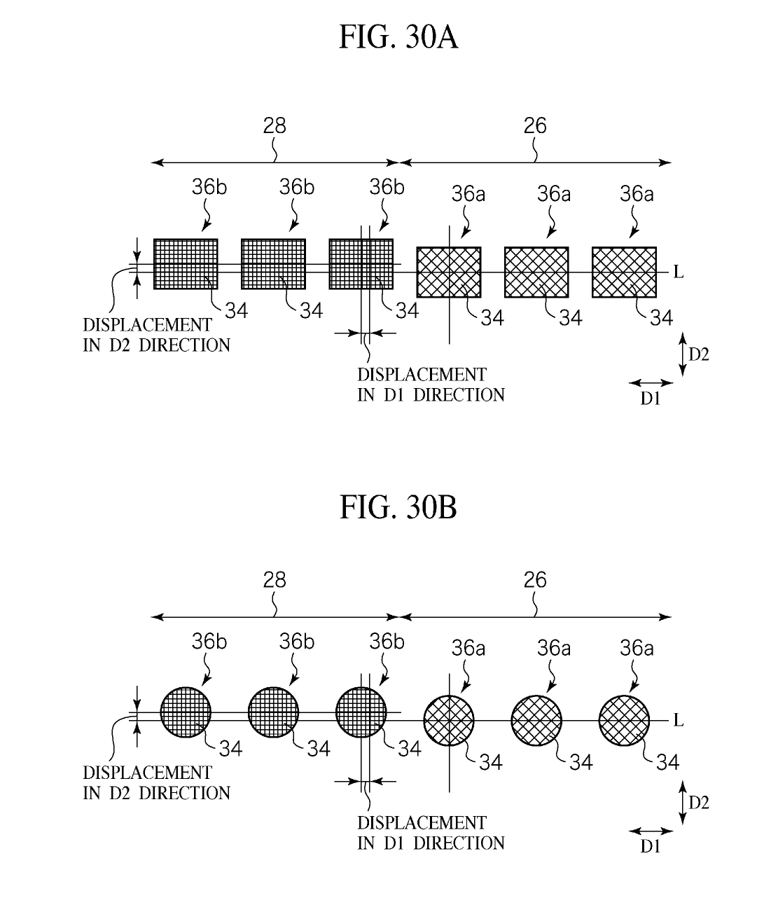

FIG. 30A and FIG. 30B are plan views showing the displacements of the arrangement of the dummy capacitors 36b from the arrangement of the actually operative capacitors 36a. In FIG. 30A, the plane shapes of the actually operative capacitors 36a and the dummy capacitors 36b are rectangular. In FIG. 30B, the plane shapes of the actually operative capacitors 36a and the dummy capacitors 36b are circular.

As illustrated in FIGS. 30A and 30B, in a case that the dummy capacitor 36b arranged in the D1 direction is displaced in the D2 direction normal to the D1 direction, the displacement in the D2 direction may be, e.g., 10% or less of the width of the actually operative capacitor 36a in the D2 direction. In other words, the center of gravity of the plane shape of the dummy capacitor 36b arranged in the D1 direction may be positioned in the D2 direction at a distance of, e.g., 10% or less of the width of the actually operative capacitor 36a in the D2 direction from the straight line L in the D1 direction passing the center of gravity of the plane shape of the actually operative capacitor 36a. This is the same with the displacement of the dummy capacitor 36b in the D1 direction.

Similarly, in the above-described embodiments, as exemplified in FIGS. 3 to 5, the arrangement of the plug portions 42 or the contact plugs 106 in the dummy capacitor part 28 is in alignment with the arrangement of the plug portions 42 or the contact plugs 106 in the actually operative capacitor part 26. However, the arrangement of the plug portions 42 or the contact plugs 106 in the dummy capacitor part 28 may not be essentially in alignment with the arrangement of the plug portions 42 or the contact plugs 106 in the actually operative capacitor part 26. In the case of FIG. 30A and FIG. 30B as well, in a case that the plug portion 42 or the contact plug 106 in the dummy capacitor part 28 arranged in the D1 direction is displaced in the D2 direction, the displacement in the D2 direction may be, e.g., 10% or less of the width of the plug portion 42 or the contact plug 106 in the actually operative capacitor part 26 in the D2 direction. In other words, the center of gravity of the plane shape of the plug portion 42 or the contact plug 106 in the dummy capacitor part 28 arranged in the D1 direction may be positioned in the D2 direction at a distance of, e.g., 10% or less of the width of the plug portion 42 or the contact plug 106 in the actually operative capacitor part 26 in the D2 direction from the straight line in the D1 direction passing the center of gravity of the plane shape of the plug portion 42 or the contact plug 106 in the actually operative capacitor part 26. This is the same with the displacement of the plug portion 42 or the contact plug 106 in the dummy capacitor part 28 in the D1 direction.

Similarly, in the above-described embodiments, as exemplified in FIGS. 3 to 5, the arrangement of the interconnections 40 in the dummy capacitor part 28 is in alignment with the arrangement of the interconnections 40 in the actually operative capacitor part 26. However, the arrangement of the interconnections in the dummy capacitor part 28 may not be essentially in alignment with the arrangement of the interconnections 40 in the actually operative capacitor part 26. As in the case of FIG. 30A and FIG. 30B, in a case that the interconnection 40 in the dummy capacitor part 28 arranged in the D1 direction is displaced in the D2 direction, the displacement in the D2 direction may be, e.g., 10% or less of the width of the interconnection 40 in the actually operative capacitor part 26 in the D2 direction. In other words, the center of gravity of the plane shape of the interconnection 40 in the dummy capacitor part 28 may be positioned in the D2 direction at a distance of, e.g., 10% or less of the width of the interconnection 40 in the actually operative capacitor part 26 in the D2 direction from the straight line in the D1 direction passing the center of gravity of the plane shape of the interconnection 40 in the actually operative capacitor part 26. This is the same with the displacement of the interconnection 40 in the dummy capacitor part 28 in the D1 direction.

In the above-described embodiments, the interconnections 40 in the dummy capacitor part 28 are connected to the upper electrodes 34 of the dummy capacitors 36b via the plug portions 42 or the contact plugs 106. However, the interconnections 40 in the dummy capacitor part 28 may not be essentially connected to the upper electrodes 34. For example, in the semiconductor device according to the second embodiment, the contact plugs 106 may not be formed.

According to the present embodiment, the interconnections are formed also over the dummy capacitors in the same manner as the interconnections formed over the actually operative capacitors, whereby the hydrogen and water residual amounts over the dummy capacitors can be decreased, and the influence of hydrogen and water on the actually operative capacitors at the end of the actually operative capacitor part can be suppressed. The same interconnection structure as that over the actually operative capacitors is formed over the dummy capacitors, whereby stresses applied to the actually operative capacitors at the end of the actually operative capacitor part can be made homogeneous. Thus, according to the present embodiment, the deterioration of the performance of the actually operative capacitors from the end of the actually operative capacitor part due to hydrogen and water and inhomogeneous stresses can be suppressed, and the lifetime characteristics of the FeRAM can be improved.

The number of each embodiment has nothing to do with the importance of the invention.

The many features and advantages of the embodiments are apparent from the detailed specification and, thus, it is intended by the appended claims to cover all such features and advantages of the embodiments that fall within the true spirit and scope thereof. Further, since numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

1. A semiconductor device comprising:
a plurality of actually operative capacitors formed, arranged in a first region over a semiconductor substrate, and each including a first lower electrode, a first ferroelectric film formed on the first lower electrode and a first upper electrode formed on the first ferroelectric film;
a plurality of dummy capacitors formed, arranged in a second region provided outside of the first region over the semiconductor substrate, each including a second lower electrode, a second ferroelectric film formed on the second lower electrode and a second upper electrode formed on the second ferroelectric film;
an inter-layer insulating film formed, including a first insulation film, a first diffusion preventing film and a second insulation film, over the plurality of the actually operative capacitors and the plurality of the dummy capacitors;
a plurality of first interconnections respectively formed in the first region over the inter-layer insulating film, and electrically coupled to an external interconnection;
a plurality of second interconnections respectively formed in the second region over the inter-layer insulating film, and electrically isolated from the external interconnection;
a plurality of first plug portions formed, respectively in the inter-layer insulating film, and respectively interconnecting the first upper electrodes of the plurality of the actually operative capacitors and the first interconnections, and formed respectively between the first upper electrodes and the plurality of the first interconnections; and
a plurality of second plug portions formed, respectively in the inter-layer insulating film, and respectively interconnecting the second upper electrodes of the plurality of the dummy capacitors and the second interconnections, and formed respectively between the second upper electrodes and the plurality of the second interconnections;
wherein a plane shape of one of the plurality of the second interconnections is the same as a plane shape of one of the plurality of the first interconnections.

2. The semiconductor device according to claim 1, wherein the first lower electrode is composed of a first portion of a conductive pattern extended from the first region to the second region, and the second lower electrode is composed of a second portion of the conductive pattern.

3. The semiconductor device according to claim 1, wherein surfaces of the first interconnections and second interconnections are planarized.

4. The semiconductor device according to claim 1, further comprising a second diffusion preventing film formed over the first interconnections and the second interconnections.

5. The semiconductor device according to claim 4, further comprising a plurality of third plug portions formed, respectively penetrated through the second diffusion preventing film and respectively connected to the plurality of the first interconnections, over the plurality of the actually operative capacitors.
